(19) United States
(12) Patent Application Publication
(10) Pub. No.: US 2024/0339973 A1
(43) Pub. Date: Oct. 10, 2024

(54) HIGH FREQUENCY MODULE AND COMMUNICATION DEVICE

(71) Applicant: Murata Manufacturing Co., Ltd., Kyoto (JP)

(72) Inventor: Masashi HAYAKAWA, Kyoto (JP)

(21) Appl. No.: 18/591,374

(22) Filed: Feb. 29, 2024

(30) Foreign Application Priority Data
Apr. 10, 2023 (JP) 2023-063749

(51) Int. Cl. H03F 3/24; H03F 1/56

(52) U.S. Cl. CPC H03F 3/245; H03F 1/56; H03F 2200/165; H03F 2200/222; H03F 2200/451

(57) ABSTRACT

A high frequency module includes a switch circuit, a first antenna terminal, a second antenna terminal, a matching circuit, a first filter, and a second filter. The switch circuit includes first to fourth terminals. The first antenna terminal is connected to the first terminal with a first signal path interposed therebetween. The second antenna terminal is connected to the second terminal with a second signal path interposed therebetween. The matching circuit is connected between the first signal path and the second signal path. The first filter is connected to the third terminal. The second filter is connected to the fourth terminal. When one terminal among the first terminal and the second terminal is connected to the third terminal or the fourth terminal, another terminal among the first terminal and the second terminal is connected to a ground.

### CROSS REFERENCE TO RELATED APPLICATION

This application claims priority from Japanese Patent Application No. 2023-063749 filed on Apr. 10, 2023. The content of this application is incorporated herein by reference in its entirety.

### BACKGROUND ART

The present disclosure relates to a high frequency module and a communication device, and more specifically, to a high frequency module and a communication device including a switch circuit and a matching circuit.

A switch module described in International Publication No. 2014/103532 includes a first antenna electrode, a second antenna electrode, a first switch IC, a matching circuit, a second switch IC, a first filter, and a second filter. The first switch IC includes a first antenna terminal connected to the first antenna electrode, a second antenna terminal connected to the second antenna electrode, and a first common terminal connected to the matching circuit. The second switch IC includes a second common terminal connected to the matching circuit, a first signal electrode connected to the first filter, and a second signal electrode connected to the second filter.

In the switch module, when the first antenna electrode is used, for example, in the first switch IC, the first common terminal is connected to the first antenna terminal, and in the second switch IC, the second common terminal is connected to the first signal electrode or the second signal electrode. Further, when the second antenna electrode is used, for example, in the first switch IC, the first common terminal is connected to the second antenna terminal, and in the second switch IC, the second common terminal is connected to the first signal electrode or the second signal electrode.

### BRIEF SUMMARY

Since the switch module described in International Publication No. 2014/103532 includes two switch ICs (the first switch IC and the second switch IC), there is a problem in that it is difficult to miniaturize the switch module. Further, since two switch ICs are included as described above, there is a problem in that the pass loss (for example, deterioration in reception sensitivity and decrease in transmission power) over the entire switch ICs becomes large. Further, there is also a problem in that it is difficult to miniaturize the matching circuit by suppressing the pass loss.

The present disclosure provides a high frequency module and a communication device that can achieve both suppression of pass loss and miniaturization.

A high frequency module according to an aspect of the present disclosure includes a switch circuit, a first antenna terminal, a second antenna terminal, a matching circuit, a first filter, and a second filter. The switch circuit includes a first terminal, a second terminal, a third terminal, and a fourth terminal. The first antenna terminal is connected to the first terminal with a first signal path interposed therebetween. The second antenna terminal is connected to the second terminal with a second signal path interposed therebetween. The matching circuit is connected between the first signal path and the second signal path. The first filter is connected to the third terminal and is configured to be connectable to one path among the first signal path and the second signal path. The second filter is connected to the fourth terminal and is configured to be connectable to another path among the first signal path and the second signal path. The first terminal and the second terminal are each configured to be selectively connectable to the third terminal, the fourth terminal, and a ground. When one terminal among the first terminal and the second terminal is connected to the third terminal or the fourth terminal, another terminal among the first terminal and the second terminal is connected to the ground.

A high frequency module according to another aspect of the present disclosure includes a switch circuit, a first amplifier circuit, a second amplifier circuit, a matching circuit, a first filter, and a second filter. The switch circuit includes a first terminal, a second terminal, a third terminal, and a fourth terminal. The first amplifier circuit is connected to the first terminal with a first signal path interposed therebetween. The second amplifier circuit is connected to the second terminal with a second signal path interposed therebetween. The matching circuit is connected between the first signal path and the second signal path. The first filter is connected to the third terminal and is configured to be connectable to one path among the first signal path and the second signal path. The second filter is connected to the fourth terminal and is configured to be connectable to another path among the first signal path and the second signal path. The first terminal and the second terminal are each configured to be selectively connectable to the third terminal, the fourth terminal, and a ground. When one terminal among the first terminal and the second terminal is connected to the third terminal or the fourth terminal, another terminal among the first terminal and the second terminal is connected to the ground.

A communication device according to still another aspect of the present disclosure includes the high frequency module and a signal processing circuit. The signal processing circuit is connected to the high frequency module and performs signal processing on a high frequency signal.

According to the high frequency module and the communication device according to the present disclosure, there is an advantage that both suppression of pass loss and miniaturization can be achieved.

### BRIEF DESCRIPTION OF THE DRAWINGS

FIG. 1 is a configuration diagram of a high frequency module and a communication device according to Embodiment 1;

FIG. 2 is a configuration diagram of a switch circuit included in the high frequency module same as the above;

FIG. 3A is a configuration diagram for explaining an operation when a first antenna terminal is used in the high frequency module same as the above; FIG. 3B is a configuration diagram showing an equivalent circuit of a matching circuit when the first antenna terminal is used in the high frequency module same as the above;

FIG. 4A is a configuration diagram for explaining an operation when a second antenna terminal is used in the high frequency module same as the above; FIG. 4B is a configuration diagram showing an equivalent circuit of the matching circuit when the second antenna terminal is used in the high frequency module same as the above;

FIG. 5 is a configuration diagram showing a specific example of a symmetrical circuit of the matching circuit according to Modification Example 1;

FIG. 6 is a configuration diagram showing another specific example of a symmetrical circuit of the matching circuit according to Modification Example 1;

FIG. 7 is a configuration diagram showing still another specific example of a symmetrical circuit of the matching circuit according to Modification Example 1;

FIG. 8 is a configuration diagram showing still another specific example of a symmetrical circuit of the matching circuit according to Modification Example 1;

FIG. 9A is a configuration diagram showing a specific example of an asymmetrical circuit of the matching circuit according to Modification Example 2; FIG. 9B is a configuration diagram showing an equivalent circuit of the matching circuit same as the above when the first antenna terminal is used; FIG. 9C is a configuration diagram showing an equivalent circuit of the matching circuit same as above when the second antenna terminal is used;

FIG. 10A is a configuration diagram showing another specific example of an asymmetrical circuit of the matching circuit according to Modification Example 2; FIG. 10B is a configuration diagram showing the equivalent circuit of the matching circuit same as the above when the first antenna terminal is used; FIG. 10C is a configuration diagram showing an equivalent circuit of the matching circuit same as above when the second antenna terminal is used;

FIGS. 11A and 11B are explanatory diagrams for explaining a disposition relationship of main portions of the high frequency module according to Modification Example 4, in which FIG. 11A is a plan view of the high frequency module same as the above, and FIG. 11B is a cross-sectional view of the high frequency module same as the above;

FIGS. 12A and 12B are explanatory diagrams for explaining a disposition relationship of main portions of the high frequency module according to Modification Example 5, in which FIG. 12A is a plan view of the high frequency module same as the above, and FIG. 12B is a cross-sectional view of the high frequency module same as the above;

FIG. 13 is a configuration diagram of a high frequency module and a communication device according to Embodiment 2;

FIG. 14 is a configuration diagram of a switch circuit included in the high frequency module same as the above;

FIG. 15 is a plan view showing a disposition relationship of terminals of the switch circuit same as the above;

FIG. 16 is a configuration diagram of main portions of a high frequency module according to Embodiment 3; and

FIG. 17 is a configuration diagram of main portions of a high frequency module according to Modification Example 1 of Embodiment 3.

### DETAILED DESCRIPTION

### Embodiment 1

Hereinafter, a communication device 100 including a high frequency module according to Embodiment 1 will be described in detail with reference to the drawings.

### (1) Overview

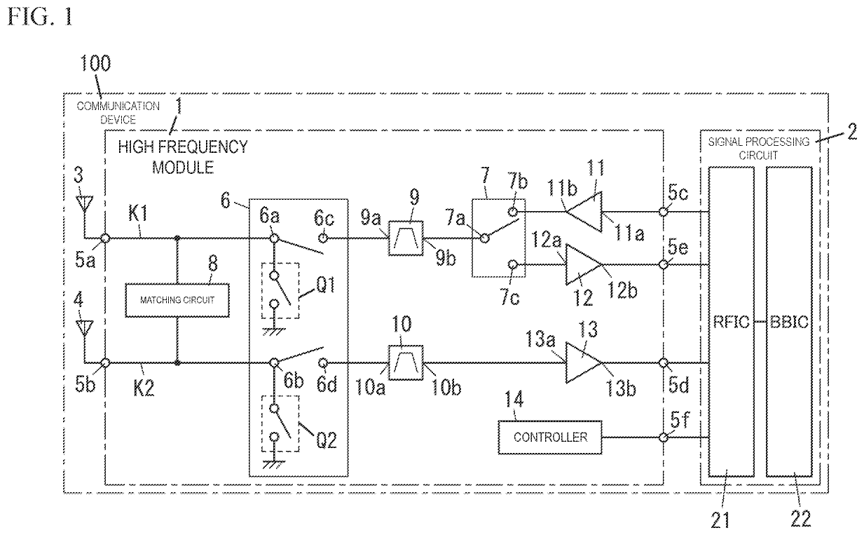

As shown in FIG. 1, a high frequency module 1 according to Embodiment 1 includes a switch circuit 6, a first antenna terminal 5a, a second antenna terminal 5b, a matching circuit 8, a first filter 9, and a second filter 10. The switch circuit 6 includes a first terminal 6a, a second terminal 6b, a third terminal 6c, and a fourth terminal 6d. The first antenna terminal 5a is connected to the first terminal 6a with a first signal path K1 interposed therebetween. The second antenna terminal 5b is connected to the second terminal 6b with a second signal path K2 interposed therebetween. The matching circuit 8 is connected between the first signal path K1 and the second signal path K2. The first filter 9 is connected to the third terminal 6c and is configured to be connectable to one path among the first signal path K1 and the second signal path K2. The second filter 10 is connected to the fourth terminal 6d and is configured to be connectable to the other path among the first signal path K1 and the second signal path K2. The first terminal 6a and the second terminal 6b are each configured to be selectively connectable to the third terminal 6c, the fourth terminal 6d, and a ground. When one terminal among the first terminal 6a and the second terminal 6b is connected to the third terminal 6c or the fourth terminal 6d, the other terminal among the first terminal 6a and the second terminal 6b is connected to the ground.

According to this configuration, the switch circuit 6 is provided on a side of the filters 9 and 10 of the matching circuit 8, but no switch circuit is provided on a side of the antenna terminals 5a and 5b of the matching circuit 8. Therefore, since no switch circuit is provided on the side of the antenna terminals 5a and 5b of the matching circuit 8, the number of switch circuits can be suppressed. As a result, the miniaturization of the high frequency module 1 can be achieved. Further, the matching circuit 8 serves as both a matching circuit for achieving impedance matching between the first antenna terminal 5a and the switch circuit 6 and a matching circuit for achieving impedance matching between the second antenna terminal 5b and the switch circuit 6. Accordingly, the miniaturization of the high frequency module 1 can be achieved. Further, since the number of switch circuits can be suppressed as described above, the pass loss over the entire switch circuits can be suppressed. Further, when one terminal (in-use terminal) among the first terminal 6a and the second terminal 6b is connected to the third terminal 6c or the fourth terminal 6d, the other terminal (not-in-use terminal) among the first terminal 6a and the second terminal 6b is connected to the ground. Therefore, it is possible to suppress unnecessary signals from circulating from the not-in-use terminal to the signal path, which is in use. As a result, it is possible to suppress the deterioration in communication loss (for example, deterioration in reception sensitivity and decrease in transmission power) in the signal path, which is in use. As described above, both suppression of communication loss and miniaturization can be achieved.

### (2) Configuration of Communication Device

As shown in FIG. 1, the communication device 100 is a communication device that includes the high frequency module 1. The communication device 100 is, for example, a mobile terminal (for example, a smart phone), but is not limited to this, and may be, for example, a wearable terminal (for example, a smart watch). The high frequency module 1 is a module compatible with, for example, a 4G (fourth generation mobile communication) standard and a 5G (fifth generation mobile communication) standard. The 4G standard is, for example, a third generation partnership project (3GPP) (registered trademark) long term evolution (LTE) (registered trademark) standard. The 5G standard is, for example, 5G new radio (NR).

The communication device 100 includes, in addition to the high frequency module 1, a signal processing circuit 2 and one or more (for example, two) antennas (a first antenna 3 and a second antenna 4).

The high frequency module 1 is configured to amplify a transmission signal (a high frequency signal) output from the signal processing circuit 2 and transmit the amplified signal from the first antenna 3 or the second antenna 4. Further, the high frequency module 1 is configured to amplify a reception signal (a high frequency signal) received by the first antenna 3 or the second antenna 4 and output the amplified signal to the signal processing circuit 2. The high frequency module 1 is controlled by the signal processing circuit 2, for example.

The signal processing circuit 2 is connected to the high frequency module 1 and is configured to perform signal processing on the transmission signal output to the high frequency module 1 or perform signal processing on the reception signal output from the high frequency module 1. The signal processing circuit 2 includes a radio frequency (RF) signal processing circuit 21 and a baseband signal processing circuit 22.

The RF signal processing circuit 21 is, for example, a radio frequency integrated circuit (RFIC) and performs the signal processing on the high frequency signal (the transmission signal and the reception signal). The RF signal processing circuit 21 performs the signal processing such as down-conversion on the reception signal, which is output from the high frequency module 1, and outputs the processed reception signal to the baseband signal processing circuit 22. Further, the RF signal processing circuit 21 performs the signal processing such as up-conversion on the transmission signal, which is output from the baseband signal processing circuit 22, and outputs the processed transmission signal to the high frequency module 1.

The baseband signal processing circuit 22 is, for example, a baseband integrated circuit (BBIC). The baseband signal processing circuit 22 outputs the reception signal, which is output from the RF signal processing circuit 21, to the outside. For example, this output signal (the reception signal) is used for image display as an image signal or is used for communication as an audio signal. Further, the baseband signal processing circuit 22 generates the transmission signal from a baseband signal (for example, the audio signal and the image signal), which is input from the outside, and outputs the generated transmission signal to the RF signal processing circuit 21.

### (3) Configuration of High Frequency Module

As shown in FIG. 1, the high frequency module 1 includes a plurality of external terminals 5a to 5f, the switch circuit 6, the matching circuit 8, the first filter 9, and the second filter 10. The high frequency module 1 further includes a switch circuit 7, a power amplifier 11, low noise amplifiers 12 and 13, and a controller 14. The switch circuit 7, the power amplifier 11, the low noise amplifiers 12 and 13, and the controller 14 are only exemplary configurations, and are not limited to such configurations.

The external terminal 5a is an antenna terminal (the first antenna terminal) to which the first antenna 3 is connected. The external terminal 5b is an antenna terminal (the second antenna terminal) to which the second antenna 4 is connected. The external terminal 5c is connected to an output portion of the signal processing circuit 2 and is an input terminal into which the transmission signal, which is output from the output portion of the signal processing circuit 2, is input. The external terminals 5d and 5e are connected to input portions of the signal processing circuit 2 and are output terminals for outputting the reception signal, which is processed by the high frequency module 1, to the input portions of the signal processing circuit 2. The external terminal 5f is connected to a signal output portion of the signal processing circuit 2 and is a signal input terminal for inputting a control signal, which is for controlling the controller 14, from the signal processing circuit 2. Hereinafter, the external terminal 5a may be described as a first antenna terminal 5a, the external terminal 5b may be described as a second antenna terminal 5b, the external terminal 5c may be described as an input terminal 5c, the external terminals 5d and 5e may be described as output terminals 5d and 5e, and the external terminal 5f may be described as a signal input terminal 5f.

The switch circuit 6 is a switch (an antenna switch) for selecting one antenna to be used from among the first antenna 3 and the second antenna 4, and for connecting the selected antenna to the first filter 9 or the second filter 10. In high frequency module 1, it is assumed that the switch circuit 6 does not select both the first antenna 3 and the second antenna 4 at the same time (that is, does not perform simultaneous communication by using the first antenna 3 and the second antenna 4). The switch circuit 6 is controlled in response to a control signal from the controller 14. The switch circuit 6 is, for example, a switch integrated circuit (IC).

The switch circuit 6 includes the first terminal 6a, the second terminal 6b, the third terminal 6c, a fourth terminal 6d, and switching elements Q1 and Q2. The first terminal 6a and the second terminal 6b are, for example, common terminals, and the third terminal 6c and the fourth terminal 6d are, for example, selection terminals. The first terminal 6a is connected to the first antenna terminal 5a with the first signal path K1 interposed therebetween. The second terminal 6b is connected to the second antenna terminal 5b with the second signal path K2 interposed therebetween. The third terminal 6c is connected to an input and output portion 9a of the first filter 9. The fourth terminal 6d is connected to an input portion 10a of the second filter 10.

The first terminal 6a and the second terminal 6b are each selectively connectable to the third terminal 6c, the fourth terminal 6d, and the ground. The first terminal 6a is connected to the ground with the switching element Q1 interposed therebetween and is selectively connected to the ground by switching the switching element Q1 ON and OFF. The second terminal 6b is connected to the ground with the switching element Q2 interposed therebetween and is selectively connected to the ground by switching the switching element Q2 ON and OFF. In the high frequency module 1, when one terminal among the first terminal 6a and the second terminal 6b is selectively connected to the third terminal 6c or the fourth terminal 6d, the other terminal among the first terminal 6a and the second terminal 6b is selectively connected to the ground.

The switch circuit 7 is a switch for selecting one amplifier to be used among the power amplifier 11 and the low noise amplifier 12, and for connecting the selected amplifier to an input and output portion 9b of the first filter 9. The switch circuit 7 is controlled in response to the control signal from the controller 14. The switch circuit 7 is, for example, a switch IC. The switch circuit 7 includes a common terminal 7a and a plurality of (two in the example in FIG. 1) selection terminals 7b and 7c. The common terminal 7a is selectively connected to one of the plurality of selection terminals 7b and 7c. The common terminal 7a is connected to the input and output portion 9b of the first filter 9. The selection terminal 7b is connected to an output portion 11b of the power amplifier 11. The selection terminal 7c is connected to an input portion 12a of the low noise amplifier 12.

The first filter 9 is, for example, a transmission and reception filter that uses a transmission and reception band of a first communication band as a communication band. In Embodiment 1, although the first filter 9 is a transmission and reception filter, the first filter 9 is not limited to a transmission and reception filter. The first filter 9 includes the input and output portions 9a and 9b. The input and output portion 9a is connected to the third terminal 6c of the switch circuit 6 and is configured to be connectable to one path among the first signal path K1 and the second signal path K2. The input and output portion 9b is connected to the common terminal 7a of the switch circuit 7. When the switch circuit 7 selects the power amplifier 11, the first filter 9 inputs an amplification signal (a transmission signal) of the power amplifier 11, which is output from the common terminal 7a of the switch circuit 7, from the input and output portion 9b. The first filter 9 restricts the input amplification signal to a signal in the transmission and reception band of the first communication band and passes the signal, and outputs the passed amplification signal from the input and output portion 9a. Further, when the switch circuit 7 selects the low noise amplifier 12, the first filter 9 inputs the reception signal, which is output from the third terminal 6c of the switch circuit 6, from the input and output portion 9a. The first filter 9 restricts the input reception signal to a signal in the transmission and reception band of the first communication band and passes the reception signal, and outputs the passed reception signal from the input and output portion 9b.

The second filter 10 is, for example, a reception filter that uses a reception band of a second communication band as a communication band. The second communication band is a communication band different from the first communication band. In Embodiment 1, although the second filter 10 is a reception filter, the second filter 10 is not limited to a reception filter. The second filter 10 includes the input portion 10a and an output portion 10b. The input portion 10a is connected to the fourth terminal 6d of the switch circuit 6 and is configured to be connectable to the other path among the first signal path K1 and the second signal path K2. The output portion 10b is connected to an input portion 13a of the low noise amplifier 13. The second filter 10 inputs the reception signal, which is output from the fourth terminal 6d of the switch circuit 6, from the input portion 10a, restricts the input reception signal to a signal in the reception band of the second communication band and passes the signal, and outputs the passed reception signal from the output portion 10b.

The matching circuit 8 is connected between the first signal path K1 and the second signal path K2. The matching circuit 8 is a matching circuit for achieving impedance matching between the first antenna terminal 5a and the switch circuit 6 and a matching circuit for achieving impedance matching between the second antenna terminal 5b and the switch circuit 6. That is, the matching circuit 8 serves as the two matching circuits described above.

More specifically, the matching circuit 8 is configured to achieve impedance matching between the first antenna terminal 5a or the second antenna terminal 5b and the switch circuit 6 when the first filter 9 is used (that is, when a signal in the communication band of the first communication band flows) through the impedance of the matching circuit 8.

Further, the matching circuit 8 is also configured to achieve impedance matching between the first antenna terminal 5a or the second antenna terminal 5b and the switch circuit 6 when the second filter 10 is used (that is, when a signal in the communication band of the second communication band flows) through the impedance of the matching circuit 8. In a case where it is difficult to achieve sufficient impedance matching between the first antenna terminal 5a or the second antenna terminal 5b and the switch circuit 6 when the second filter 10 is used with only an impedance value of the matching circuit 8, an impedance value of the second filter 10 is set to an appropriate value, and the matching circuit 8 may be configured to achieve impedance matching between the first antenna terminal 5a or the second antenna terminal 5b and the switch circuit 6 when the second filter 10 is used by combining the impedance value of the matching circuit 8 and the impedance value of the second filter 10.

The power amplifier 11 is connected between the external terminal 5c and the selection terminal 7b of the switch circuit 7. The power amplifier 11 includes an input portion 11a and the output portion 11b. The input portion 11a is connected to the external terminal 5c. The output portion 11b is connected to the selection terminal 7b of the switch circuit 7. The power amplifier 11 amplifies a signal (a transmission signal) input from the external terminal 5c to the input portion 11a and outputs the amplified signal from the output portion 11b to the selection terminal 7b.

The low noise amplifier 12 is connected between the selection terminal 7c of the switch circuit 7 and the external terminal 5e. The low noise amplifier 12 includes the input portion 12a and an output portion 12b. The input portion 12a is connected to the selection terminal 7c of the switch circuit 7. The output portion 12b is connected to the external terminal 5e. The low noise amplifier 12 amplifies a signal (a reception signal) input from the selection terminal 7c to the input portion 12a and outputs the amplified signal from the output portion 12b to the external terminal 5e.

The low noise amplifier 13 is connected between the output portion 10b of the second filter 10 and the external terminal 5d. The low noise amplifier 13 includes the input portion 13a and an output portion 13b. The input portion 13a is connected to the output portion 10b of the second filter 10. The output portion 13b is connected to the external terminal 5d. The low noise amplifier 13 amplifies a signal (a reception signal) input from the output portion 10b of the second filter 10 to the input portion 13a and outputs the amplified signal from the output portion 13b to the external terminal 5d.

The controller 14 controls electronic components (for example, the switch circuits 6 and 7, the power amplifier 11, and the low noise amplifiers 12 and 13) included in the high frequency module 1 in response to a control signal from the signal processing circuit 2. The controller 14 is electrically connected with the above-mentioned electronic components. Further, the controller 14 is connected to the signal output portion of the signal processing circuit 2 with the external terminal 5f interposed therebetween. The controller 14 controls each of the electronic components in response to the control signal input from the signal processing circuit 2 to the external terminal 5f.

### (4) Detailed Configuration of Switch Circuit 6

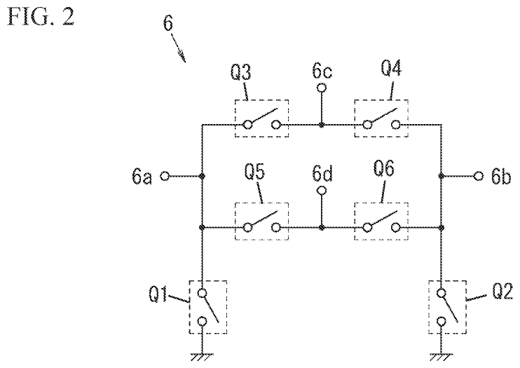

A detailed configuration of the switch circuit 6 will be described with reference to FIG. 2.

The switch circuit 6 further includes switching elements Q3 to Q6 in addition to the first to fourth terminals 6a to 6d and the switching elements Q1 and Q2.

As described above, the switching element Q1 is provided between the first terminal 6a and the ground, and switches connection and disconnection between the first terminal 6a and the ground. As described above, the switching element Q2 is provided between the second terminal 6b and the ground, and switches connection and disconnection between the second terminal 6b and the ground. The switching element Q3 is provided between the first terminal 6a and the third terminal 6c, and switches connection and disconnection between the first terminal 6a and the third terminal 6c. The switching element Q4 is provided between the second terminal 6b and the third terminal 6c, and switches connection and disconnection between the second terminal 6b and the third terminal 6c. The switching element Q5 is provided between the first terminal 6a and the fourth terminal 6d, and switches connection and disconnection between the first terminal 6a and the fourth terminal 6d. The switching element Q6 is provided between the second terminal 6b and the fourth terminal 6d, and switches connection and disconnection between the second terminal 6b and the fourth terminal 6d.

In this switch circuit 6, a case is considered in which the first terminal 6a is selectively connected to the third terminal 6c among the third terminal 6c, the fourth terminal 6d, and the ground (that is, in a case where the first terminal 6a is used among the first terminal 6a and the second terminal 6b). In this case, the switching element Q3 is controlled to be ON, and the switching elements Q1 and Q5 are controlled to be OFF. As a result, the first terminal 6a is selectively connected to the third terminal 6c. In this case, the switching element Q2 is controlled to be ON, and the switching elements Q4 and Q6 are controlled to be OFF. As a result, the second terminal 6b, which is not in use, is selectively connected to the ground and is not connected to the third terminal 6c and the fourth terminal 6d.

Further, a case is considered in which the first terminal 6a is selectively connected to the fourth terminal 6d among the third terminal 6c, the fourth terminal 6d, and the ground (that is, in a case where the first terminal 6a is used among the first terminal 6a and the second terminal 6b). In this case, the switching element Q5 is controlled to be ON, and the switching elements Q1 and Q3 are controlled to be OFF. As a result, the first terminal 6a is selectively connected to the fourth terminal 6d. In this case, the switching element Q2 is controlled to be ON, and the switching elements Q4 and 06 are controlled to be OFF. As a result, the second terminal 6b, which is not in use, is selectively connected to the ground and is not connected to the third terminal 6c and the fourth terminal 6d.

Further, a case is considered in which the second terminal 6b is selectively connected to the third terminal 6c among the third terminal 6c, the fourth terminal 6d, and the ground (that is, in a case where the second terminal 6b is used among the first terminal 6a and the second terminal 6b). In this case, the switching element Q4 is controlled to be ON, and the switching elements Q2 and Q6 are controlled to be OFF. As a result, the second terminal 6b is selectively connected to the third terminal 6c. In this case, the switching element Q1 is controlled to be ON, and the switching elements Q3 and Q5 are controlled to be OFF. As a result, the first terminal 6a, which is not in use, is selectively connected to the ground and is not connected to the third terminal 6c and the fourth terminal 6d.

Further, a case is considered in which the second terminal 6b is selectively connected to the fourth terminal 6d among the third terminal 6c, the fourth terminal 6d, and the ground (that is, in a case where the second terminal 6b is used among the first terminal 6a and the second terminal 6b). In this case, the switching element Q6 is controlled to be ON, and the switching elements Q2 and Q4 are controlled to be OFF. As a result, the second terminal 6b is selectively connected to the fourth terminal 6d. In this case, the switching element Q1 is controlled to be ON, and the switching elements Q3 and 05 are controlled to be OFF. As a result, the first terminal 6a, which is not in use, is selectively connected to the ground and is not connected to the third terminal 6c and the fourth terminal 6d.

### (5) Operation of High Frequency Module

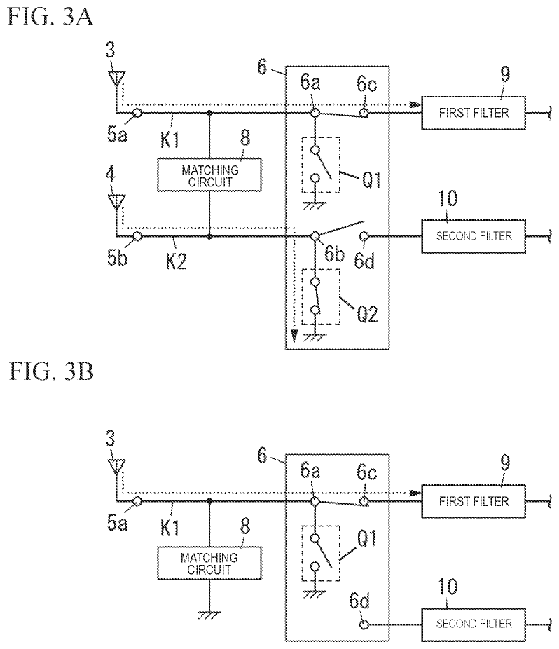

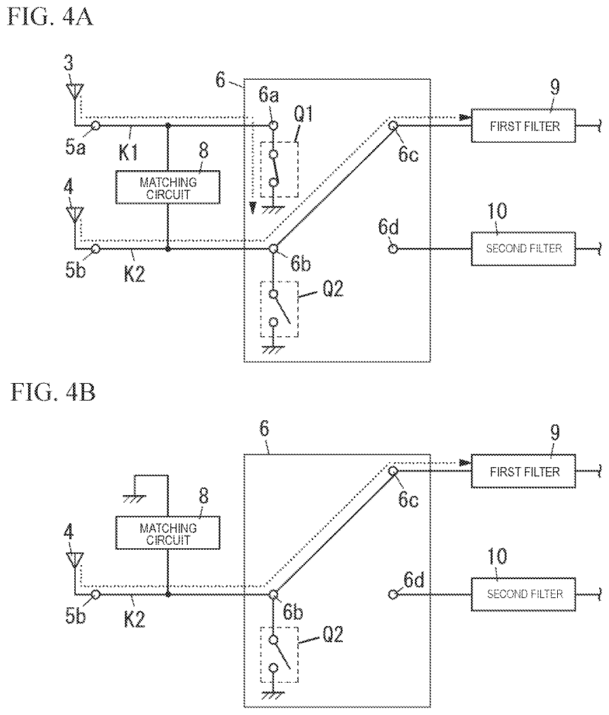

The operation of the high frequency module 1 will be described with reference to FIGS. 3A to 4B. More specifically, the operation of the high frequency module 1 will be described with a focus on the operation of the switch circuit 6.

As shown in FIG. 3A, a case will be described in which the first antenna terminal 5a is connected to one of the first filter 9 and the second filter 10 (the first filter 9 in the example in FIG. 3A), and the second antenna terminal 5b is not connected to both the first filter 9 and the second filter 10. That is, a case is considered in which the first antenna terminal 5a is used and the second antenna terminal 5b is not used. In this case, the switch circuit 7 may connect the first filter 9 to either the power amplifier 11 or the low noise amplifier 12. In the example in FIG. 3A, the switch circuit 7 connects the first filter 9 to the low noise amplifier 12.

In this case, in the switch circuit 6, the first terminal 6a is selectively connected to the third terminal 6c among the third terminal 6c, the fourth terminal 6d, and the ground. As a result, the first antenna terminal 5a is selectively connected to the first filter 9 by the switch circuit 6. As a result, the reception signal, in which the first antenna 3 is received, flows to the first filter 9 through the switch circuit 6. Further, the second terminal 6b is selectively connected to the ground among the third terminal 6c, the fourth terminal 6d, and the ground. As a result, the second terminal 6b connected to the second antenna terminal 5b, which is not in use, is selectively connected to the ground. As a result, unnecessary signals generated in the signal path (the second signal path K2), which is not in use, are discharged from the second terminal 6b (not-in-use terminal) to the ground. As a result, it is possible to suppress unnecessary signals from circulating from the second terminal 6b (not-in-use terminal) to the signal path (the signal path connecting the first antenna terminal 5a, the first terminal 6a, the third terminal 6c, and the first filter 9), which is in use. In this case, as shown in FIG. 3B, looking at the matching circuit 8 from the first antenna terminal 5a, which is used, one end of the matching circuit 8 (one end on the opposite side of the first signal path K1) appears to be connected to the ground.

Further, as shown in FIG. 4A, a case will be described in which the second antenna terminal 5b is selectively connected to one of the first filter 9 and the second filter 10 (the first filter 9 in the example in FIG. 4A), and the first antenna terminal 5a is not connected to both the first filter 9 and the second filter 10. In this case, the switch circuit 7 may connect the first filter 9 to either the power amplifier 11 or the low noise amplifier 12. In the example in FIG. 4A, the switch circuit 7 connects the first filter 9 to the low noise amplifier 12.

In this case, in the switch circuit 6, the second terminal 6b is selectively connected to the third terminal 6c among the third terminal 6c, the fourth terminal 6d, and the ground. As a result, the second antenna terminal 5b is selectively connected to the first filter 9 by the switch circuit 6. As a result, the reception signal, in which the second antenna 4 is received, flows to the first filter 9 through the switch circuit 6. Further, the first terminal 6a is selectively connected to the ground among the third terminal 6c, the fourth terminal 6d, and the ground. As a result, the first terminal 6a connected to the first antenna terminal 5a, which is not in use, is selectively connected to the ground. As a result, unnecessary signals generated in the signal path (the first signal path K1), which is not in use, are discharged from the first terminal 6a (not-in-use terminal) to the ground. As a result, it is possible to suppress unnecessary signals from circulating from the first terminal 6a (not-in-use terminal) to the signal path (the signal path connecting the second antenna terminal 5b, the second terminal 6b, the third terminal 6c, and the first filter 9), which is in use. In this case, as shown in FIG. 4B, looking at the matching circuit 8 from the second antenna terminal 5b, which is used, one end of the matching circuit 8 (one end on the opposite side of the second signal path K2) appears to be connected to the ground.

As described above, when one terminal (in-use terminal) among the first terminal 6a and the second terminal 6b is connected to the third terminal 6c or the fourth terminal 6d, the other terminal (not-in-use terminal) among the first terminal 6a and the second terminal 6b is connected to the ground. As a result, it is possible to suppress unnecessary signals from circulating from the not-in-use terminal to the in-use terminal side. As a result, it is possible to suppress the deterioration in communication loss (for example, deterioration in reception sensitivity and decrease in transmission power) in the signal path, which is in use.

Further, the matching circuit 8 serves as both matching circuits of a matching circuit for achieving impedance matching between the first antenna terminal 5a and the switch circuit 6 and a matching circuit for achieving impedance matching between the second antenna terminal 5b and the switch circuit 6. Therefore, the miniaturization of the high frequency module 1 can be achieved.

### (6) Effects

As described above, a high frequency module 1 according to Embodiment 1 includes a switch circuit 6, a first antenna terminal 5a, a second antenna terminal 5b, a matching circuit 8, a first filter 9, and a second filter 10. The switch circuit 6 includes a first terminal 6a, a second terminal 6b, a third terminal 6c, and a fourth terminal 6d. The first antenna terminal 5a is connected to the first terminal 6a with a first signal path K1 interposed therebetween. The second antenna terminal 5b is connected to the second terminal 6b with a second signal path K2 interposed therebetween. The matching circuit 8 is connected between the first signal path K1 and the second signal path K2. The first filter 9 is connected to the third terminal 6c. The second filter 10 is connected to the fourth terminal 6d. The first terminal 6a and the second terminal 6b are each configured to be selectively connectable to the third terminal 6c, the fourth terminal 6d, and a ground. When one terminal among the first terminal 6a and the second terminal 6b is connected to the third terminal 6c or the fourth terminal 6d, the other terminal among the first terminal 6a and the second terminal 6b is connected to the ground.

According to this configuration, the switch circuit 6 is provided on a side of the filters 9 and 10 of the matching circuit 8, but no switch circuit is provided on a side of the antenna terminals 5a and 5b of the matching circuit 8. Therefore, since no switch circuit is provided on the side of the antenna terminals 5a and 5b of the matching circuit 8, the number of switch circuits can be suppressed. As a result, the miniaturization of the high frequency module 1 can be achieved. Further, the matching circuit 8 serves as both a matching circuit for achieving impedance matching between the first antenna terminal 5a and the switch circuit 6 and a matching circuit for achieving impedance matching between the second antenna terminal 5b and the switch circuit 6. Accordingly, the miniaturization of the high frequency module 1 can be achieved.

Further, since the number of switch circuits can be suppressed as described above, the pass loss over the entire switch circuits can be suppressed. Further, when one terminal (in-use terminal) among the first terminal 6a and the second terminal 6b is connected to the third terminal 6c or the fourth terminal 6d, the other terminal (not-in-use terminal) among the first terminal 6a and the second terminal 6b is connected to the ground. Therefore, it is possible to suppress unnecessary signals from circulating from the not-in-use terminal to the signal path, which is in use. As a result, it is possible to suppress the deterioration in communication loss (for example, deterioration in reception sensitivity and decrease in transmission power) in the signal path, which is in use.

As described above, both suppression of communication loss and miniaturization can be achieved.

Further, the communication device 100 according to Embodiment 1 includes the high frequency module 1 and the signal processing circuit 2. The signal processing circuit 2 is connected to the high frequency module 1 and performs signal processing on a high frequency signal. According to this configuration, the communication device 100 having the effect of the high frequency module 1 can be obtained.

### (7) Modification Examples

Hereinafter, modification examples of Embodiment 1 will be described.

### (7-1) Modification Example 1

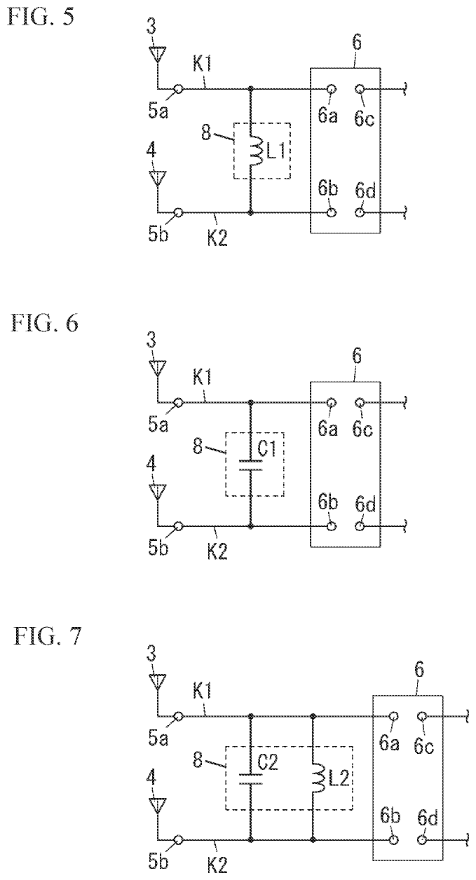

In Modification Example 1, specific examples (FIGS. 5 to 8) of a circuit configuration of the matching circuit 8 are exemplified. The matching circuits 8 shown in FIGS. 5 to 8 are symmetrical circuits.

The “symmetrical circuit” means that a first equivalent circuit and a second equivalent circuit of the matching circuit 8 are the same. The first equivalent circuit is an equivalent circuit of the matching circuit 8 when the first terminal 6a is selectively connected to the third terminal 6c or the fourth terminal 6d (that is, the first antenna terminal 5a is used) and when the second terminal 6b is selectively connected to the ground (that is, the second antenna terminal 5b is not used), in the switch circuit 6. The second equivalent circuit is an equivalent circuit of the matching circuit 8 when the first terminal 6a is selectively connected to the ground (that is, the first antenna terminal 5a is not used) and when the second terminal 6b is selectively connected to the third terminal 6c or the fourth terminal 6d (that is, the second antenna terminal 5b is used), in the switch circuit 6.

The matching circuit 8 shown in FIG. 5 includes an inductor L1 connected between the first signal path K1 and the second signal path K2. The matching circuit 8 in this case configures a high pass type matching circuit. In this case, the first equivalent circuit of the matching circuit 8 is a circuit configuration in which the inductor L1 is connected between the first signal path K1 and the ground. The second equivalent circuit is a circuit configuration in which the inductor L1 is connected between the second signal path K2 and the ground. Therefore, the first equivalent circuit and the second equivalent circuit are the same.

The matching circuit 8 shown in FIG. 6 includes a capacitor C1 connected between the first signal path K1 and the second signal path K2. The matching circuit 8 in this case configures a low pass type matching circuit. In this case, the first equivalent circuit and the second equivalent circuit of the matching circuit 8 are the same.

The matching circuit 8 shown in FIG. 7 is connected between the first signal path K1 and the second signal path K2, and includes an inductor L2 and a capacitor C2 connected in parallel to each other. That is, a parallel circuit of the inductor L2 and the capacitor C2 is connected between the first signal path K1 and the second signal path K2. The matching circuit 8 in this case configures a band pass type matching circuit. In this case, the first equivalent circuit and the second equivalent circuit of the matching circuit 8 are the same.

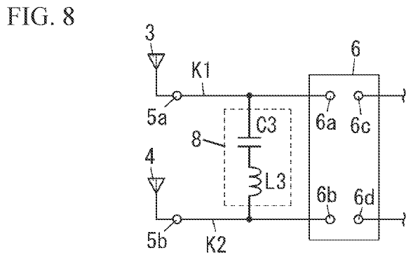

The matching circuit 8 shown in FIG. 8 is connected between the first signal path K1 and the second signal path K2, and includes an inductor L3 and a capacitor C3 connected in series to each other. That is, a series circuit of the inductor L3 and the capacitor C3 is connected between the first signal path K1 and the second signal path K2. The matching circuit 8 in this case configures a band elimination type matching circuit. In this case, the first equivalent circuit and the second equivalent circuit of the matching circuit 8 are the same.

### (7-2) Modification Example 2

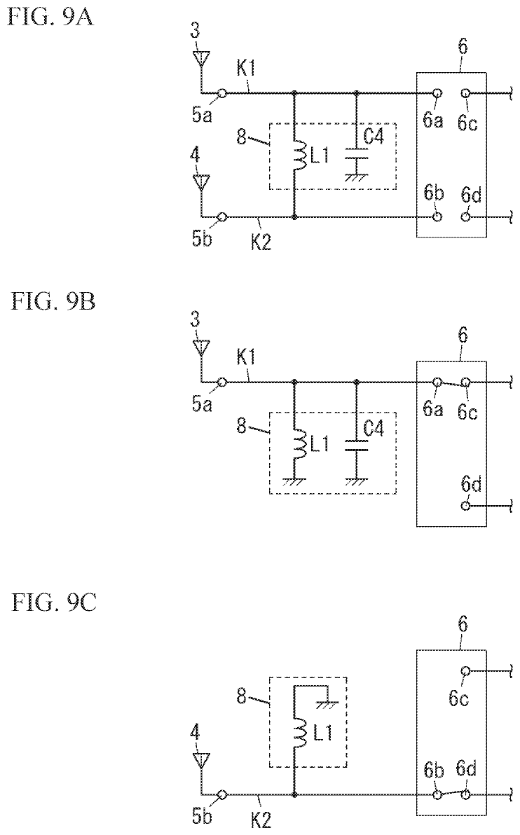

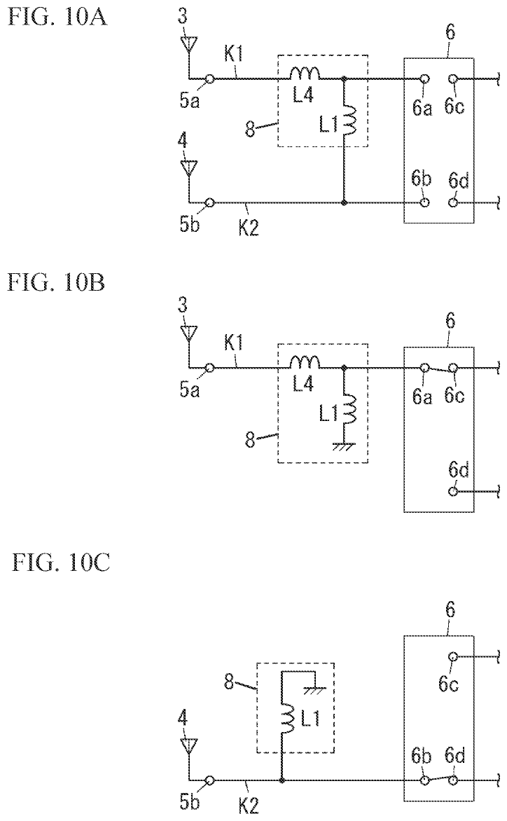

In Modification Example 2, specific examples (FIGS. 9A to 10C) of a circuit configuration of the matching circuit 8 when the matching circuit 8 is an asymmetrical circuit are exemplified. The “asymmetrical circuit” means that the first equivalent circuit and the second equivalent circuit of the matching circuit 8 are different from each other. The definitions of the first equivalent circuit and the second equivalent circuit are the same as those of Modification Example 1.

The matching circuit 8 shown in FIG. 9A includes the inductor L1 connected between the first signal path K1 and the second signal path K2, and a capacitor C4 connected between the first signal path K1 and the ground.

In this case, as shown in FIG. 9B, in the first equivalent circuit of the matching circuit 8, the capacitor C4 and the inductor L1 are each connected between the first signal path K1 and the ground. In this case, the first equivalent circuit of the matching circuit 8 is a band pass type matching circuit. In the example in FIG. 9B, a case is illustrated in which the first terminal 6a is selectively connected to the third terminal 6c.

On the other hand, as shown in FIG. 9C, in the second equivalent circuit of the matching circuit 8, the inductor L1 is connected between the second signal path K2 and the ground, and both ends of the capacitor C4 are connected to the ground so that the capacitor C4 is substantially eliminated from the configuration of the matching circuit 8. In this case, the second equivalent circuit of the matching circuit 8 is a high pass type matching circuit. In the example in FIG. 9C, a case is illustrated in which the second terminal 6b is selectively connected to the fourth terminal 6d.

Although the matching circuit 8 shown in FIG. 9A has a configuration in which the capacitor C4 is added to the matching circuit 8 shown in FIG. 5, the matching circuit 8 shown in FIG. 9A may have a configuration in which the capacitor C4 is added to another circuit (for example, the matching circuit 8 shown in FIG. 6, FIG. 7 or FIG. 8) instead of the matching circuit 8 shown in FIG. 5.

The matching circuit 8 shown in FIG. 10A includes the inductor L1 connected between the first signal path K1 and the second signal path K2 and the inductor L4 connected in series to a portion of the first signal path K1 between the first antenna terminal 5a and the inductor L1.

In this case, as shown in FIG. 10B, in the first equivalent circuit of the matching circuit 8, the inductor L4 is connected in series to the first signal path K1, and the inductor L1 is connected between the first signal path K1 and the ground.

On the other hand, as shown in FIG. 10C, in the second equivalent circuit of the matching circuit 8, the inductor L1 is connected between the second signal path K2 and the ground, and the inductor L4 is substantially eliminated from the configuration of matching circuit 8. In this case, the second equivalent circuit of the matching circuit 8 is a high pass type matching circuit.

Although the matching circuit 8 shown in FIG. 10A has a configuration in which the inductor L4 is added to the matching circuit 8 shown in FIG. 5, the matching circuit 8 shown in FIG. 10A may have a configuration in which the inductor L4 is added to another circuit (for example, the matching circuit 8 shown in FIG. 6, FIG. 7 or FIG. 8) instead of the matching circuit 8 shown in FIG. 5.

As described above, the matching circuit 8 of Modification Example 2 is switchable between the first equivalent circuit and the second equivalent circuit without using a switching element. Therefore, the matching circuit 8 of Modification Example 2 can switch between the first equivalent circuit and the second equivalent circuit without reducing a Q value.

Further, the equivalent circuit of the matching circuit 8 can be switched to the first equivalent circuit and the second equivalent circuit when the first antenna terminal 5a is selected and when the second antenna terminal 5b is selected. As a result, even when the filter (the first filter 9 or the second filter 10), which is in use, is different when the first antenna terminal 5a is selected and when the second antenna terminal 5b is selected, it is possible to achieve impedance matching between the first antenna terminal 5a and the switch circuit 6 and impedance matching between the second antenna terminal 5b and the switch circuit 6 with only an impedance value of the matching circuit 8. That is, even when the impedance is different between the first antenna terminal 5a and the second antenna terminal 5b, impedance matching between the first antenna terminal 5a and the second antenna terminal 5b, and the switch circuit 6 can be achieved by the matching circuit 8.

### (7-3) Modification Example 3

In Embodiment 1, the matching circuit 8 may include an inductor formed on a mounting board. In this case, the inductor may be formed in a pattern on a mounting board on which a plurality of electronic components of the high frequency module 1 are mounted. The plurality of electronic components include the switch circuits 6 and 7, the matching circuit 8, the first filter 9, the second filter 10, the power amplifier 11, the low noise amplifiers 12 and 13, and the controller 14. For example, the inductor may be patterned by an electric path provided on the mounting board. According to Modification Example 3, the miniaturization can be achieved on the high frequency module 1 as compared with a case where the inductor is configured as a surface mount device.

### (7-4) Modification Example 4

In Modification Example 4, a disposition relationship of the main portions (the first antenna terminal 5a, the second antenna terminal 5b, the matching circuit 8, and the switch circuit 6) of the high frequency module 1 of Embodiment 1 is exemplified.

### (7-4-1) Configuration Description

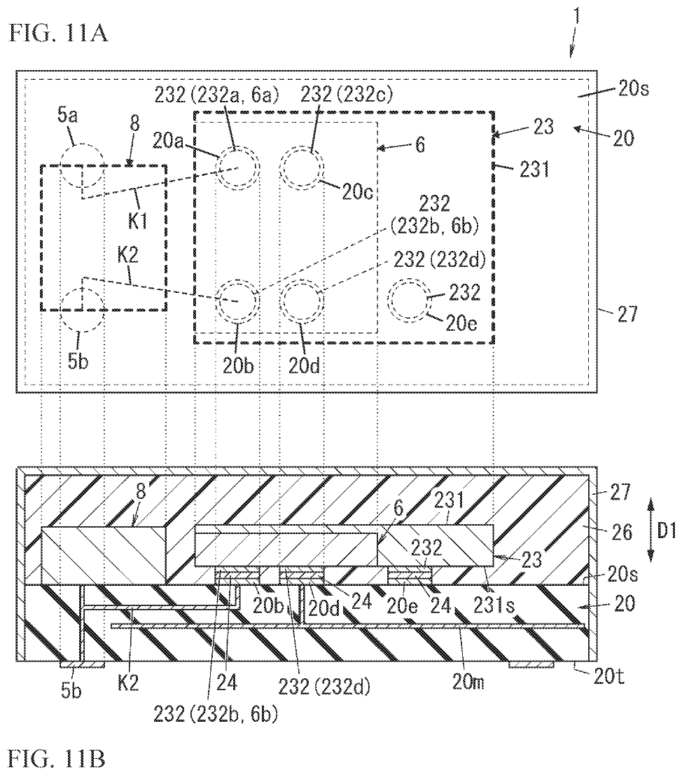

As shown in FIGS. 11A and 11B, in Modification Example 4, the high frequency module 1 further includes a mounting board 20, a resin layer 26, and a shield layer 27 in the high frequency module 1 of Embodiment 1. In Modification Example 4, the high frequency module 1 further includes an integrated circuit (IC) chip 23 including the switch circuit 6.

The mounting board 20 is a board on which the plurality of electronic components of the high frequency module 1 are mounted, and has, for example, a rectangular plate shape. The plurality of electronic components include the switch circuit 6 (the IC chip 23) described in Embodiment 1, the switch circuit 7, the matching circuit 8, the first filter 9, the second filter 10, the power amplifier 11, the low noise amplifiers 12 and 13, and the controller 14. In the example in FIG. 11, only the matching circuit 8 and the IC chip 23 are illustrated among the plurality of electronic components described above, and other electronic components are omitted.

The mounting board 20 is a board (multilayer board) having a plurality of layers including a plurality of dielectric layers and a plurality of conductive layers. The plurality of dielectric layers and the plurality of conductive layers are laminated in a thickness direction D1 of the mounting board 20. The plurality of conductive layers are formed in a predetermined pattern determined for each layer. The plurality of conductive layers include a ground layer 20m connected to a ground potential. The ground layer 20m is connected to the shield layer 27 at least a part of an outer peripheral surface of the mounting board 20.

The mounting board 20 includes a first main surface 20s and a second main surface 20t that face each other in the thickness direction D1 of the mounting board 20. A plurality of pads 20a to 20e are provided on the first main surface 20s of the mounting board 20. The plurality of pads 20a to 20e are connected to the conductive layer with via electrodes in the mounting board 20 interposed therebetween.

The first main surface 20s of the mounting board 20 is provided with the plurality of electronic components, the resin layer 26, and the shield layer 27. That is, in Modification Example 4, the mounting board 20 is a one-sided mounting board on which the plurality of electronic components are mounted on one side of the mounting board 20. More specifically, the plurality of electronic components are disposed (mounted) on the first main surface 20s of the mounting board 20. As described above, in the example in FIG. 11, only the matching circuit 8 and the IC chip 23 are illustrated among the plurality of electronic components described above.

The IC chip 23 is disposed at a predetermined position on the first main surface 20s of the mounting board 20. The IC chip 23 has, for example, a rectangular plate shape in a plan view. The IC chip 23 includes a chip main body 231 and a plurality of external terminals 232. The chip main body 231 has, for example, a rectangular plate shape in a plan view. The chip main body 231 includes switching elements Q1 to 06 (see FIG. 2) configuring the switch circuit 6. The plurality of external terminals 232 are disposed on a surface 231s facing the mounting board 20 in the chip main body 231. The plurality of external terminals 232 are connected to the plurality of pads 20a to 20e provided on the first main surface 20s of the mounting board 20 with solders 24 interposed therebetween.

The plurality of external terminals 232 include external terminals 232a to 232d.

The external terminal 232a configures the first terminal 6a of the switch circuit 6. The external terminal 232a is connected to the pad 20a of the mounting board 20 with the solder 24 interposed therebetween. The pad 20a is connected to the first antenna terminal 5a with the first signal path K1 interposed therebetween. The first signal path K1 is formed with the conductive layer and the via electrode of the mounting board 20.

The external terminal 232b configures the second terminal 6b of the switch circuit 6. The external terminal 232b is connected to the pad 20b of the mounting board 20 with the solder 24 interposed therebetween. The pad 20b is connected to the second antenna terminal 5b with the second signal path K2 interposed therebetween. The second signal path K2 is formed with the conductive layer and the via electrode of the mounting board 20.

The external terminal 232c is a ground terminal for connecting the external terminal 232a to the ground layer 20m of the mounting board 20. The external terminal 232c is connected to the external terminal 232a (the first terminal 6a) with the switching element Q1 (see FIG. 1) in the chip main body 231 interposed therebetween. As a result, the external terminal 232c is connected to the external terminal 232a to be switchable between connection and disconnection. The external terminal 232c is connected to the pad 20c, which is provided on the first main surface 20s of the mounting board 20, with the solder 24 interposed therebetween. The pad 20c is connected to the ground layer 20m with the via electrode and the conductive layer in the mounting board 20 interposed therebetween. That is, the external terminal 232c is connected to the ground with the ground layer 20m interposed therebetween.

The external terminal 232d is a ground terminal for connecting the external terminal 232b to the ground layer 20m of the mounting board 20. The external terminal 232d is connected to the external terminal 232b (the second terminal 6b) with the switching element Q2 (see FIG. 1) in the chip main body 231 interposed therebetween. As a result, the external terminal 232d is connected to the external terminal 232b to be switchable between connection and disconnection. The external terminal 232d is connected to the pad 20d, which is provided on the first main surface 20s of the mounting board 20, with the solder 24 interposed therebetween. The pad 20d is connected to the ground layer 20m with the via electrode and the conductive layer in the mounting board 20 interposed therebetween. That is, the external terminal 232d is connected to the ground with the ground layer 20m interposed therebetween.

Although a case where the external terminals 232c and 232d are provided for each external terminal 232a and 232b is exemplified, the external terminals 232c and 232d may be shared between the external terminals 232a and 232b.

The matching circuit 8 is disposed (mounted) at a predetermined position on the first main surface 20s of the mounting board 20. The matching circuit 8 has, for example, a rectangular plate shape in a plan view. The matching circuit 8 is electrically connected to the first signal path K1 and the second signal path K2 with the via electrode and the conductive layer in the mounting board 20 interposed therebetween.

The resin layer 26 is provided on the first main surface 20s of the mounting board 20 to cover the plurality of electronic components. The resin layer 26 is a layer formed of a resin and may contain a filler in addition to the resin.

The shield layer 27 is formed of, for example, metal. The shield layer 27 is provided to cover the surface of the resin layer 26 and the outer peripheral surface of the mounting board 20. The shield layer 27 is connected to the ground layer 20m at least a part of the outer peripheral surface of the mounting board 20. As a result, the shield layer 27 is connected to the ground potential with the ground layer 20m interposed therebetween.

The plurality of external terminals 5a to 5f (see FIG. 1) described in Embodiment 1 are disposed on the second main surface 20t of the mounting board 20. In Modification Example 4, the plurality of external terminals 5a to 5f have, for example, a circular flat plate shape in a plan view. In the example in FIG. 11, only the external terminals 5a and 5b are illustrated among the plurality of external terminals 5a to 5f, and the other external terminals 5c to 5f are omitted. Here, as described in Embodiment 1, the external terminal 5a is the first antenna terminal 5a, and the external terminal 5b is the second antenna terminal 5b. The first antenna terminal 5a is connected to the external terminal 232a of the IC chip 23 with the first signal path K1 and the pad 20a, which are provided on the mounting board 20, interposed therebetween. The second antenna terminal 5b is connected to the external terminal 232b of the IC chip 23 with the second signal path K2 and the pad 20b, which are provided on the mounting board 20, interposed therebetween.

### (7-4-2) Description of Disposition Relationship of Main Portions of High Frequency Module

A disposition relationship of the main portions (the first antenna terminal 5a, the second antenna terminal 5b, the matching circuit 8, and the switch circuit 6) of the high frequency module 1 is described with reference to FIGS. 11A and 11B.

In Modification Example 4, the matching circuit 8 is disposed to be adjacent to the IC chip 23 (that is, the switch circuit 6) on the first main surface 20s of the mounting board 20. As a result, the signal path between the matching circuit 8 and the IC chip 23 can be shortened. Here, the fact that “the matching circuit 8 is adjacent to the IC chip 23” means that no other electronic component is disposed between the matching circuit 8 and the IC chip 23.

Further, the first antenna terminal 5a and the second antenna terminal 5b are disposed on the second main surface 20t of the mounting board 20 to overlap the matching circuit 8 in a plan view from the thickness direction D1 of the mounting board 20. As a result, the signal path between the first antenna terminal 5a and the second antenna terminal 5b, and the matching circuit 8 can be shortened. Here, the fact that “the first antenna terminal 5a and the second antenna terminal 5b overlap the matching circuit 8” means that at least a part of each of the first antenna terminal 5a and the second antenna terminal 5b overlaps the matching circuit 8.

Further, the switch circuit 6 is disposed, for example, on the matching circuit 8 side, inside the IC chip 23. The fact that “the switch circuit 6 is disposed on the matching circuit 8 side, inside the IC chip 23” means that the center of the switch circuit 6 in a plan view is positioned on the matching circuit 8 side of the center of the IC chip 23 in a plan view. More specifically, the switch circuit 6 is disposed, for example, near a side surface (more specifically, the side surface adjacent to the matching circuit 8) of the IC chip 23, inside the IC chip 23. As a result, the signal path between the switch circuit 6 and the matching circuit 8 can be shortened.

Further, the external terminals 232a and 232b are disposed to overlap the switch circuit 6 in a plan view from the thickness direction D1 of the mounting board 20. Further, the external terminal 232c is disposed to be adjacent to the external terminal 232a (that is, as described above, the external terminal connected to the external terminal 232c with the switching element Q1 interposed therebetween, in the IC chip 23). The external terminal 232d is disposed to be adjacent to the external terminal 232b (that is, as described above, the external terminal connected to the external terminal 232d with the switching element Q2 interposed therebetween, in the IC chip 23). Accordingly, the signal path between the external terminals 232a and 232c, and the signal path between the external terminals 232b and 232d can be shortened. Here, the fact that “the external terminal (for example, 232c) is adjacent to the external terminal (for example, 232a)” means that no other external terminal 232 is disposed between the external terminal (for example, 232c) and the external terminal (for example, 232a).

With such a disposition relationship, the signal path to the first antenna terminal (the external terminal) 5a, the first terminal (the external terminal) 6a, the ground terminal (the external terminal) 232c, and the ground layer 20m can be shortened. Similarly, the signal path to the second antenna terminal (the external terminal) 5b, the second terminal (the external terminal) 6b, the ground terminal (the external terminal) 232d, and the ground layer 20m can be shortened. As a result, parasitic components (parasitic inductor and parasitic capacitance) generated in the signal path can be reduced. As a result, it is possible to suppress the pass loss (for example, deterioration in reception sensitivity and decrease in transmission power) in the signal path, which is in use.

### (7-5) Modification Example 5

In Modification Example 4, the disposition relationship of the main portions of the high frequency module 1 when the mounting board 20 is a one-sided mounting board is exemplified. In contrast to this, in Modification Example 5, the disposition relationship of the main portions of the high frequency module 1 when the mounting board 20 is a double-sided mounting board is exemplified.

### (7-5-1) Configuration Description

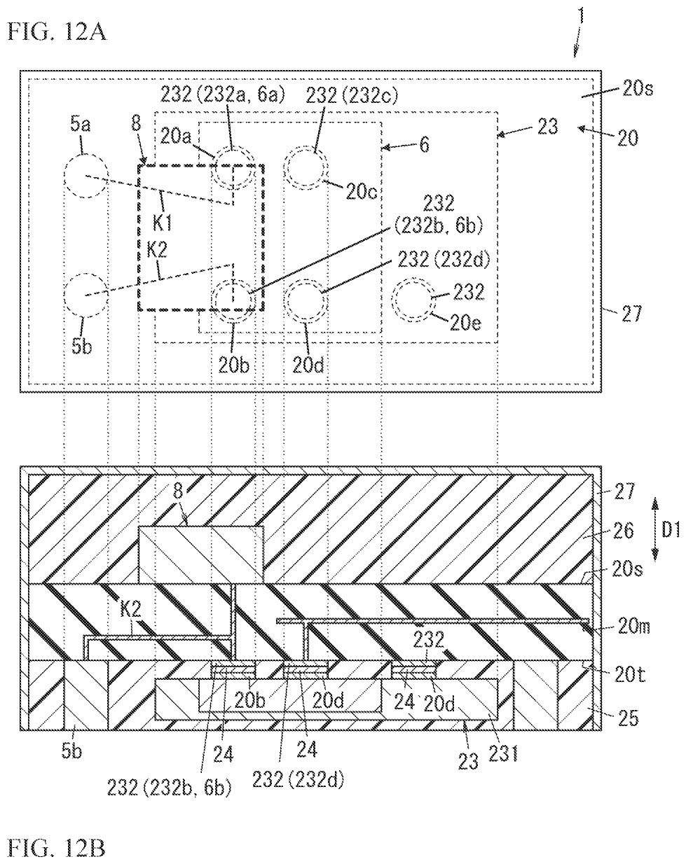

As shown in FIGS. 12A and 12B, the high frequency module 1 of Modification Example 5 is different from the high frequency module 1 of Modification Example 4 in that the IC chip 23 is disposed on the second main surface 20t of the mounting board 20 and a resin layer 25 is further included on the second main surface 20t of the mounting board 20.

In Modification Example 5, the plurality of external terminals 5a to 5f are formed, for example, in a cylindrical shape and are disposed to rise from the second main surface 20t of the mounting board 20. In FIGS. 12A and 12B, only the external terminal 5b is illustrated among the plurality of external terminals 5a to 5f, and the other external terminals 5a and 5c to 5f are omitted. Further, the resin layer 25 is provided on the second main surface 20t of the mounting board 20 to cover the entire IC chip 23 and the outer peripheral surfaces of each of the external terminals 5a to 5f. The outer peripheral surface of the resin layer 25 is covered with the shield layer 27.

### (7-5-2) Description of Disposition Relationship of Main Portions of High Frequency Module

Next, the disposition relationship of the main portions of the high frequency module 1 according to Modification Example 5 will be described with reference to FIGS. 12A and 12B.

In Modification Example 5, the matching circuit 8 is disposed on the first main surface 20s of the mounting board 20 to overlap the IC chip 23 in a plan view from the thickness direction D1 of the mounting board 20. More specifically, the matching circuit 8 is disposed on the first main surface 20s of the mounting board 20 to overlap the switch circuit 6 in a plan view from the thickness direction D1 of the mounting board 20. As a result, the signal path between the matching circuit 8 and the IC chip 23 (more specifically, the switch circuit 6) can be shortened. Here, the fact that “the matching circuit 8 overlaps the IC chip 23 or the switch circuit 6” means that at least a part of the matching circuit 8 overlaps the IC chip 23 or the switch circuit 6.

Further, the matching circuit 8 is disposed on the first main surface 20s of the mounting board 20 to overlap each of the external terminals 232a and 232b in a plan view from the thickness direction D1 of the mounting board 20. As a result, the signal path between the matching circuit 8, and the external terminals 232a and 232b can be shortened. Here, the fact that “the matching circuit 8 overlaps each of the external terminals 6a and 6b” means that the matching circuit 8 overlaps at least a part of each of the external terminals 6a and 6b.

Further, the external terminal 232c is disposed to be adjacent to the external terminal 232a (that is, as described above, the external terminal connected to the external terminal 232c with the switching element Q1 interposed therebetween, in the IC chip 23). The external terminal 232d is disposed to be adjacent to the external terminal 232b (that is, as described above, the external terminal connected to the external terminal 232d with the switching element Q2 interposed therebetween, in the IC chip 23). Accordingly, the signal path between the external terminals 232a and 232c, and the signal path between the external terminals 232b and 232d can be shortened. Here, the fact that “the external terminal (for example, 232c) is adjacent to the external terminal (for example, 232a)” means that no other external terminal 232 is disposed between the external terminal (for example, 232c) and the external terminal (for example, 232a).

With such a disposition relationship, the signal path to the first antenna terminal (the external terminal) 5a, the first terminal (the external terminal) 6a, the ground terminal (the external terminal) 232c, and the ground layer 20m can be shortened. Similarly, the signal path to the second antenna terminal (the external terminal) 5b, the second terminal (the external terminal) 6b, the ground terminal (the external terminal) 232d, and the ground layer 20m can be shortened. As a result, parasitic components (parasitic inductor and parasitic capacitance) generated in the signal path can be reduced. As a result, it is possible to suppress the pass loss (for example, deterioration in reception sensitivity and decrease in transmission power) in the signal path, which is in use.

### Embodiment 2

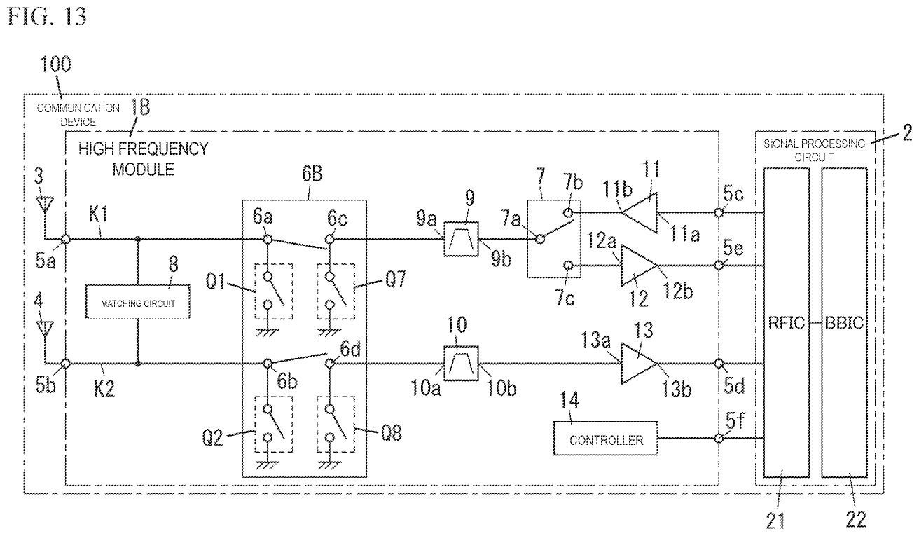

A high frequency module 1B according to Embodiment 2 will be described with reference to FIGS. 13 to 15.

### (1) Configuration Description

As shown in FIG. 13, a switch circuit 6B of Embodiment 2 further includes switching elements Q7 and Q8 in the switch circuit 6 of Embodiment 1. As a result, the switch circuit 6B is configured to be switchable of connection and disconnection between the third terminal 6c and the fourth terminal 6d, and the ground. That is, in the switch circuit 6B, the third terminal 6c and the fourth terminal 6d are each configured to be selectively connectable to the first terminal 6a, the second terminal 6b, and the ground. As a result, in the switch circuit 6B, when one terminal among the third terminal and the fourth terminal is connected to the first terminal or the second terminal, the other terminal among the third terminal and the fourth terminal is connected to the ground.

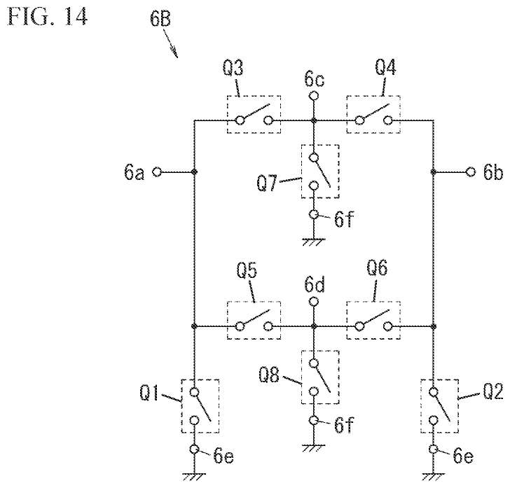

More specifically, as shown in FIG. 14, the switch circuit 6B further includes switching elements Q7 and Q8 in the switch circuit 6 (see FIG. 2) of Embodiment 1. The switching element Q7 is connected between the third terminal 6c and the second ground terminal 6f, and switches connection and disconnection between the third terminal 6c and the second ground terminal 6f. The switching element Q8 is connected between the fourth terminal 6d and the second ground terminal 6f, and switches connection and disconnection between the fourth terminal 6d and the second ground terminal 6f. In the example in FIG. 14, the switching element Q1 is connected between the first terminal 6a and the first ground terminal 6e, and switches connection and disconnection between the first terminal 6a and the first ground terminal 6e. The switching element Q2 is connected between the second terminal 6b and the first ground terminal 6e, and switches connection and disconnection between the second terminal 6b and the first ground terminal 6e. The first ground terminal 6e and the second ground terminal 6f are connected to the ground.

### (2) Operation Description

The operation of the switch circuit 6B will be described with reference to FIG. 14.

With reference to FIG. 14, in this switch circuit 6B, a case is considered in which the first terminal 6a is selectively connected to the third terminal 6c among the third terminal 6c, the fourth terminal 6d, and the first ground terminal 6e (that is, in a case where the first terminal 6a is used among the first terminal 6a and the second terminal 6b). In this case, the switching element Q3 is controlled to be ON, and the switching elements Q1, Q5, and Q7 are controlled to be OFF. As a result, the first terminal 6a is selectively connected to the third terminal 6c. In this case, the switching element Q2 is controlled to be ON, and the switching elements Q4 and Q6 are controlled to be OFF. As a result, the second terminal 6b, which is not in use, is selectively connected to the first ground terminal 6e and is not connected to the third terminal 6c and the fourth terminal 6d. Further, in this case, the switching element Q8 is controlled to be ON. As a result, the fourth terminal 6d, which is not in use, is connected to the second ground terminal 6f. Therefore, it is possible to prevent the fourth terminal 6d, which is not in use, from being in a floating state. As a result, it is possible to suppress unnecessary signals from circulating from the fourth terminal 6d to the signal path, which is in use.

Further, a case is considered in which the first terminal 6a is selectively connected to the fourth terminal 6d among the third terminal 6c, the fourth terminal 6d, and the first ground terminal 6e (that is, in a case where the first terminal 6a is used among the first terminal 6a and the second terminal 6b). In this case, the switching element Q5 is controlled to be ON, and the switching elements Q1, Q3, and Q8 are controlled to be OFF. As a result, the first terminal 6a is selectively connected to the fourth terminal 6d. In this case, the switching element Q2 is controlled to be ON, and the switching elements Q4 and Q6 are controlled to be OFF. As a result, the second terminal 6b, which is not in use, is selectively connected to the first ground terminal 6e and is not connected to the third terminal 6c and the fourth terminal 6d. Further, in this case, the switching element Q7 is controlled to be ON. As a result, the third terminal 6c, which is not in use, is connected to the second ground terminal 6f. As a result, it is possible to prevent the third terminal 6c, which is not in use, from being in a floating state. As a result, it is possible to suppress unnecessary signals from circulating from the third terminal 6c to the signal path, which is in use.

Further, a case is considered in which the second terminal 6b is selectively connected to the third terminal 6c among the third terminal 6c, the fourth terminal 6d, and the first ground terminal 6e (that is, in a case where the second terminal 6b is used among the first terminal 6a and the second terminal 6b). In this case, the switching element Q4 is controlled to be ON, and the switching elements Q2, 06, and Q7 are controlled to be OFF. As a result, the second terminal 6b is selectively connected to the third terminal 6c. In this case, the switching element Q1 is controlled to be ON, and the switching elements Q3 and Q5 are controlled to be OFF. As a result, the first terminal 6a, which is not in use, is selectively connected to the first ground terminal 6e and is not connected to the third terminal 6c and the fourth terminal 6d. Further, in this case, the switching element Q8 is controlled to be ON. As a result, the fourth terminal 6d, which is not in use, is connected to the second ground terminal 6f. Therefore, it is possible to prevent the fourth terminal 6d, which is not in use, from being in a floating state. As a result, it is possible to suppress unnecessary signals from circulating from the fourth terminal 6d to the signal path, which is in use.

Further, a case is considered in which the second terminal 6b is selectively connected to the fourth terminal 6d among the third terminal 6c, the fourth terminal 6d, and the ground (that is, in a case where the second terminal 6b is used among the first terminal 6a and the second terminal 6b). In this case, the switching element Q6 is controlled to be ON, and the switching elements Q2, 04, and Q8 are controlled to be OFF. As a result, the second terminal 6b is selectively connected to the fourth terminal 6d. In this case, the switching element Q1 is controlled to be ON, and the switching elements Q3 and Q5 are controlled to be OFF. As a result, the first terminal 6a, which is not in use, is selectively connected to the first ground terminal 6e and is not connected to the third terminal 6c and the fourth terminal 6d. Further, in this case, the switching element Q7 is controlled to be ON. As a result, the third terminal 6c, which is not in use, is connected to the second ground terminal 6f. As a result, it is possible to prevent the third terminal 6c, which is not in use, from being in a floating state. As a result, it is possible to suppress unnecessary signals from circulating from the third terminal 6c to the signal path, which is in use.

### (3) Disposition Relationship of Terminals of Switch Circuit 6B

The disposition relationship of the terminals (the first terminal 6a, the second terminal 6b, the first ground terminal 6e, and the second ground terminal 6f) of the switch circuit 6B will be described with reference to FIG. 15.

The switch circuit 6B further includes a board 61 including a main surface 61s. The circuit elements (the switching elements Q1 to Q8, the first to fourth terminals 6a to 6d, the first ground terminal 6e, and the second ground terminal 6f) configuring the switch circuit 6 are disposed on the main surface 61s of the board 61. In FIG. 15, only the first terminal 6a, the second terminal 6b, the first ground terminal 6e, and the second ground terminal 6f are illustrated among the circuit elements.

The first terminal 6a, the second terminal 6b, the first ground terminal 6e, and the second ground terminal 6f are disposed on the main surface 61s of the board 61, for example, as shown in FIG. 15. More specifically, a straight line distance between the center of the first terminal 6a and the center of the first ground terminal 6e is defined as a first distance T1 in a plan view from the thickness direction of the board 61, a straight line distance between the center of the first terminal 6a and the center of the second ground terminal 6f is defined as a second distance T2. Further, a straight line distance between the center of the second terminal 6b and the center of the first ground terminal 6e is defined as a third distance T3 in a plan view from the thickness direction of the board 61, a straight line distance between the center of the second terminal 6b and the center of the second ground terminal 6f is defined as a fourth distance T4. In this case, the first terminal 6a, the second terminal 6b, the first ground terminal 6e, and the second ground terminal 6f are disposed to satisfy Expression 1 below. (T1+T3)< (T2+T4) (Expression 1)

Expression 1 means that the sum of the first distance T1 and the third distance T3 is shorter than the sum of the second distance T2 and the fourth distance T4.

As described above, the first terminal 6a, the second terminal 6b, the first ground terminal 6e, and the second ground terminal 6f are disposed to satisfy Expression 1. As a result, the sum of the signal path between the first terminal 6a and the first ground terminal 6e, and the signal path between the second terminal 6b and the first ground terminal 6e can be shortened. As a result, parasitic components (for example, parasitic inductor and parasitic capacitance) generated in the signal path can be suppressed. As a result, it is possible to suppress the pass loss (deterioration in reception sensitivity and decrease in transmission power) in the signal path, which is in use.

### (4) Sharing of Ground Terminal of Switch Circuit 6B

As shown in FIG. 14, both the ground terminal (the first ground terminal 6e) to which the first terminal 6a is connected and the ground terminal (the first ground terminal 6e) to which the second terminal 6b is connected function as the ground terminals of the matching circuit 8. That is, since each of these ground terminals is a ground terminal having the same function as the ground terminal of the matching circuit 8, each of these ground terminals is configured with the common first ground terminal 6e.

Further, both the ground terminal (the second ground terminal 6f) to which the third terminal 6c is connected and the ground terminal (the second ground terminal 6f) to which the fourth terminal 6d is connected function as ground terminals for insulating (isolation) the third terminal 6c or the fourth terminal 6d from other terminals. That is, since each of these ground terminals is a ground terminal having the same function of insulating the third terminal 6c or the fourth terminal 6d from other terminals, each of these ground terminals is configured with the common second ground terminal 6f.

As described above, in the switch circuit 6B, a plurality of ground terminals (the first ground terminal 6e and the second ground terminal 6f) are shared for each function of the ground terminal. As a result, the miniaturization of the switch circuit 6B can be achieved. As a result, the miniaturization of the high frequency module 1B can be achieved.

### (5) Effects

As described above, in the switch circuit 6B of Embodiment 2, the third terminal 6c and the fourth terminal 6d are each configured to be selectively connectable to the first terminal 6a, the second terminal 6b, and the second ground terminal 6f. When one terminal among the third terminal 6c and the fourth terminal 6d is connected to the first terminal 6a or the second terminal 6b, the other terminal among the third terminal 6c and the fourth terminal 6d is connected to the second ground terminal 6f. According to this configuration, when one terminal among the third terminal 6c and the fourth terminal 6d is connected to the first terminal 6a or the second terminal 6b, the other terminal (not-in-use terminal) among the third terminal 6c and the fourth terminal 6d is connected to the second ground terminal 6f. As a result, it is possible to prevent the not-in-use terminal from being in a floating state. As a result, it is possible to suppress unnecessary signals from circulating from the not-in-use terminal to the signal path, which is in use.

Further, in Embodiment 2, similarly to Embodiment 1, the switch circuit 6B is provided on a side of the filters 9 and 10 of the matching circuit 8, but no switch circuit is provided on a side of the antenna terminals 5a and 5b of the matching circuit 8. Therefore, since no switch circuit is provided on the side of the antenna terminals 5a and 5b of the matching circuit 8, the number of switch circuits can be suppressed. As a result, the miniaturization of the high frequency module 1 can be achieved. Further, the matching circuit 8 serves as both a matching circuit for achieving impedance matching between the first antenna terminal 5a and the switch circuit 6 and a matching circuit for achieving impedance matching between the second antenna terminal 5b and the switch circuit 6. Accordingly, the miniaturization of the high frequency module 1 can be achieved.

### (6) Modification Examples

Modification examples of Embodiment 2 will be described.

### (6-1) Modification Example 1

In Embodiment 2, the first terminal 6a, the second terminal 6b, the first ground terminal 6e, and the second ground terminal 6f are disposed on the main surface 61s of the board 61 to satisfy Expression 1. However, the first terminal 6a, the second terminal 6b, the first ground terminal 6e, and the second ground terminal 6f may be disposed on the main surface 61s of the board 61 to satisfy Expression 2 below instead of Expression 1 described above. T1<T2 (Expression 2)

Expression 2 means that the first distance T1 is shorter than the second distance T2.

As described above, when the first terminal 6a, the second terminal 6b, the first ground terminal 6e, and the second ground terminal 6f are disposed to satisfy Expression 2, the signal path between the first terminal 6a and the first ground terminal 6e can be shortened. As a result, parasitic components (parasitic inductor and parasitic capacitance) generated in the communication path can be suppressed. As a result, it is possible to suppress the pass loss (deterioration in reception sensitivity and decrease in transmission power) in the signal path, which is in use.

### (6-2) Modification Example 2

In Embodiment 2, the first terminal 6a, the second terminal 6b, the first ground terminal 6e, and the second ground terminal 6f are disposed on the main surface 61s of the board 61 to satisfy Expression 1. However, the first terminal 6a, the second terminal 6b, the first ground terminal 6e, and the second ground terminal 6f may be disposed on the main surface 61s of the board 61 to satisfy Expression 3 below instead of Expression 1 described above. T1<T2, T1<T4, T3<T2, T3<T4 (Expression 3) Expression 3 means that the first distance T1 is shorter than the second distance T2 and the fourth distance T4, and the third distance T3 is also shorter than the second distance T2 and the fourth distance T4.

As described above, the first terminal 6a, the second terminal 6b, the first ground terminal 6e, and the second ground terminal 6f are disposed to satisfy Expression 3. As a result, the signal path between the first terminal 6a and the first ground terminal 6e, and the signal path between the second terminal 6b and the first ground terminal 6e can be shortened. Therefore, parasitic components (parasitic inductor and parasitic capacitance) generated in the communication path can be suppressed. As a result, it is possible to suppress the pass loss (deterioration in reception sensitivity and decrease in transmission power) in the signal path, which is in use.

### Embodiment 3

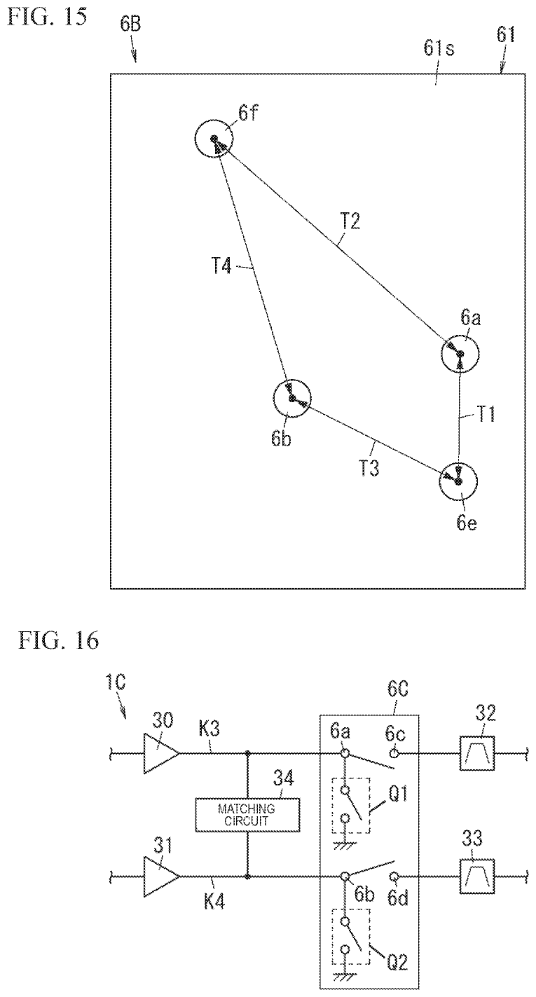

A high frequency module 1C according to Embodiment 3 will be described with reference to FIG. 16.

### (1) Configuration

In the high frequency module 1 according to Embodiment 1, the first antenna terminal 5a is connected to the first terminal 6a of the switch circuit 6 with the first signal path K1 interposed therebetween, and the second antenna terminal 5b is connected to a second terminal 6b of the switch circuit 6 with the second signal path K2 interposed therebetween (see FIG. 1). In contrast to this, in the high frequency module 1C according to Embodiment 3, as shown in FIG. 16, a first power amplifier 30 (a first amplifier circuit) is connected to the first terminal 6a of the switch circuit 6C with a first signal path K3 interposed therebetween, and a second power amplifier 31 (a second amplifier circuit) is connected to the second terminal 6b of the switch circuit 6C with a second signal path K4 interposed therebetween.

More specifically, the high frequency module 1C includes the switch circuit 6C, the first power amplifier 30, the second power amplifier 31, the matching circuit 8, a first filter 32, and a second filter 33.

The switch circuit 6C is configured similarly to the switch circuit 6 of Embodiment 1. The switch circuit 6C includes a first terminal 6a, a second terminal 6b, a third terminal 6c, and a fourth terminal 6d. In Embodiment 3, the switch circuit 6C functions as a band select switch. The first terminal 6a and the second terminal 6b are each configured to be selectively connectable to the third terminal 6c, the fourth terminal 6d, and a ground. The first terminal 6a is switched between connection and disconnection with the ground by the switching element Q1. The second terminal 6b is switched between connection and disconnection with the ground by the switching element Q2. When one terminal among the first terminal 6a and the second terminal 6b is connected to the third terminal 6c or the fourth terminal 6d, the other terminal among the first terminal 6a and the second terminal 6b is connected to the ground.

The first power amplifier 30 is connected to the first terminal 6a with the first signal path K3 interposed therebetween. The first power amplifier 30 amplifies a transmission signal from the signal processing circuit (not shown) and outputs the transmission signal to the first terminal 6a of the switch circuit 6C. The second power amplifier 31 is connected to the second terminal 6b with the second signal path K4 interposed therebetween. The second power amplifier 31 amplifies a transmission signal from the signal processing circuit (not shown) and outputs the transmission signal to the second terminal 6b of the switch circuit 6C. The matching circuit 34 is connected between the first signal path K3 and the second signal path K4.

The first filter 32 is connected to the third terminal 6c and is configured to be connectable to one path among the first signal path K3 and the second signal path K4. The first filter 32 is, for example, a transmission filter that uses a transmission band of a first communication band as a communication band. The first filter 32 restricts the transmission signal, which is output from the third terminal 6c of the switch circuit 6C, to a signal in the transmission band of the first communication band and passes the transmission signal, and outputs the passed transmission signal to a subsequent circuit. The second filter 33 is connected to the fourth terminal 6d and is configured to be connectable to the other path among the first signal path K3 and the second signal path K4. The second filter 33 is, for example, a transmission filter that uses a transmission band of a second communication band as a communication band. The second filter 33 restricts the transmission signal, which is output from the fourth terminal 6d of the switch circuit 6c, to a signal in the transmission band of the second communication band, and passes the transmission signal, and outputs the passed transmission signal to a subsequent circuit.

The same effect as that of Embodiment 1 is obtained in Embodiment 3. More specifically, according to Embodiment 3, although the switch circuit 6C is provided on the sides of the filters 32 and 33 of the matching circuit 34, no switch circuit is provided on the sides of the power amplifiers 30 and 31 of the matching circuit 34. Therefore, since no switch circuit is provided on the sides of the power amplifiers 30 and 31 of the matching circuit 34, the number of switch circuits can be suppressed. As a result, the miniaturization of the high frequency module 1C can be achieved. Further, the matching circuit 34 serves as both a matching circuit for achieving impedance matching between the first power amplifier 30 and the switch circuit 6C and a matching circuit for achieving impedance matching between the second power amplifier 31 and the switch circuit 6C. Accordingly, the miniaturization of the high frequency module 1 can be achieved. Further, since the number of switch circuits can be suppressed as described above, the pass loss over the entire switch circuits can be suppressed. Further, when one terminal (in-use terminal) among the first terminal 6a and the second terminal 6b is connected to the third terminal 6c or the fourth terminal 6d, the other terminal (not-in-use terminal) among the first terminal 6a and the second terminal 6b is connected to the ground. Therefore, it is possible to suppress unnecessary signals from circulating from the not-in-use terminal to the in-use terminal. As a result, it is possible to suppress the deterioration in communication loss (for example, deterioration in reception sensitivity and decrease in transmission power) in the signal path, which is in use. As described above, both suppression of communication loss and miniaturization can be achieved.

### (2) Modification Examples

Next, modification examples of Embodiment 3 will be described.

### (2-1) Modification Example 1

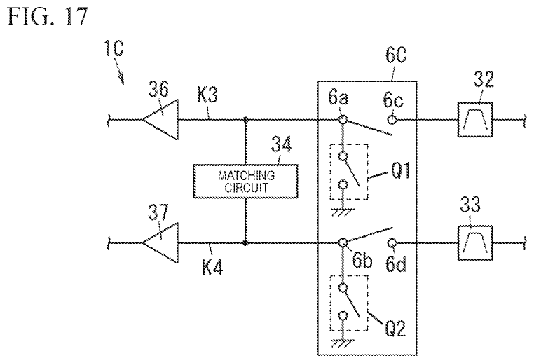

In Embodiment 3, although a case is exemplified in which the first amplifier circuit is the first power amplifier 30 and the second amplifier circuit is the second power amplifier 31, as shown in FIG. 17, the first amplifier circuit may be a first low noise amplifier 36 and the second amplifier circuit may be a second low noise amplifier 37. In this case, the first filter 32 and the second filter 33 are, for example, reception filters. The same effect as that of Embodiment 3 is obtained in Modification Example 1.

### (2-2) Other Modification Examples

Embodiments 1 to 3 and Modification examples thereof may be combined and implemented.

### Aspects

The following aspects are disclosed in the present specification.

A high frequency module (1; 1B) of a first aspect includes a switch circuit (6; 6B), a first antenna terminal (5a), a second antenna terminal (5b), a matching circuit (8), a first filter (9), and a second filter (10). The switch circuit (6; 6B) includes a first terminal (6a), a second terminal (6b), a third terminal (6c), and a fourth terminal (6d). The first antenna terminal (5a) is connected to the first terminal (6a) with the first signal path (K1) interposed therebetween. The second antenna terminal (5b) is connected to the second terminal (6b) with the second signal path (K2) interposed therebetween. The matching circuit (8) is connected between the first signal path (K1) and the second signal path (K2). The first filter (9) is connected to the third terminal (6c) and is configured to be connectable to one path among the first signal path and the second signal path. The second filter (10) is connected to the fourth terminal (6d) and is configured to be connectable to the other path among the first signal path and the second signal path. The first terminal (6a) and the second terminal (6b) are each configured to be selectively connectable to the third terminal (6c), the fourth terminal (6d), and the ground. When one terminal among the first terminal (6a) and the second terminal (6b) is connected to the third terminal (6c) or the fourth terminal (6d), the other terminal among the first terminal (6a) and the second terminal (6b) is connected to the ground.

According to this configuration, the switch circuit (6; 6B) is provided on a side of the filters (9, 10) of the matching circuit (8), but no switch circuit is provided on a side of the antenna terminals (5a, 5b) of the matching circuit (8). Therefore, since no switch circuit is provided on the side of the antenna terminals (5a, 5b) of the matching circuit (8), the number of switch circuits can be suppressed. As a result, the miniaturization of the high frequency module (1; 1B) can be achieved. Further, the matching circuit (8) serves as both a matching circuit for achieving impedance matching between the first antenna terminal (5a) and the switch circuit (6; 6B) and a matching circuit for achieving impedance matching between the second antenna terminal (5b) and the switch circuit (6; 6B). Accordingly, the miniaturization of the high frequency module (1; 1B) can be achieved. Further, since the number of switch circuits can be suppressed as described above, the pass loss over the entire switch circuits can be suppressed. Further, when one terminal (in-use terminal) among the first terminal (6a) and the second terminal (6b) is connected to the third terminal (6c) or the fourth terminal (6d), the other terminal (not-in-use terminal) among the first terminal (6a) and the second terminal (6b) is connected to the ground. Therefore, it is possible to suppress unnecessary signals from circulating from the not-in-use terminal to the signal path, which is in use. As a result, it is possible to suppress the deterioration in communication loss (for example, deterioration in reception sensitivity and decrease in transmission power) in the signal path, which is in use. As described above, both suppression of communication loss and miniaturization can be achieved.

A high frequency module (1C) of a second aspect includes a switch circuit (6C), a first amplifier circuit (30; 36), a second amplifier circuit (31; 37), a matching circuit (34), a first filter (32), and a second filter (33). The switch circuit (6C) includes a first terminal (6a), a second terminal (6b), a third terminal (6c), and a fourth terminal (6d). The first amplifier circuit (30; 36) is connected to the first terminal (6a) with the first signal path (K3) interposed therebetween. The second amplifier circuit (31; 37) is connected to the second terminal (6b) with the second signal path (K4) interposed therebetween. The matching circuit (8) is connected between the first signal path (K3) and the second signal path (K4). The first filter (32) is connected to the third terminal (6c) and is configured to be connectable to one path among the first signal path and the second signal path. The second filter (33) is connected to the fourth terminal (6d) and is configured to be connectable to the other path among the first signal path and the second signal path. The first terminal (6a) and the second terminal (6b) are each configured to be selectively connectable to the third terminal (6c), the fourth terminal (6d), and the ground. When one terminal among the first terminal (6a) and the second terminal (6b) is connected to the third terminal (6c) or the fourth terminal (6d), the other terminal among the first terminal (6a) and the second terminal (6b) is connected to the ground.

According to this configuration, the switch circuit (6C) is provided on a side of the filters (32, 33) of the matching circuit (34), but no switch circuit is provided on a side of the amplifier circuits (30, 31; 36, 37) of the matching circuit (34). Therefore, since no switch circuit is provided on the side of the amplifier circuits (30, 31; 36, 37) of the matching circuit (34), the number of switch circuits can be suppressed. As a result, the miniaturization of the high frequency module (1C) can be achieved. Further, the matching circuit (34) serves as both a matching circuit for achieving impedance matching between the first amplifier circuit (30; 36) and the switch circuit (6C) and a matching circuit for achieving impedance matching between the second amplifier circuit (31; 37) and the switch circuit (6C). Accordingly, the miniaturization of the high frequency module (1C) can be achieved. Further, since the number of switch circuits can be suppressed as described above, the pass loss over the entire switch circuits can be suppressed. Further, when one terminal (in-use terminal) among the first terminal (6a) and the second terminal (6b) is connected to the third terminal (6c) or the fourth terminal (6d), the other terminal (not-in-use terminal) among the first terminal (6a) and the second terminal (6b) is connected to the ground. Therefore, it is possible to suppress unnecessary signals from circulating from the not-in-use terminal to the signal path, which is in use. As a result, it is possible to suppress the deterioration in communication loss (for example, deterioration in reception sensitivity and decrease in transmission power) in the signal path, which is in use. As described above, both suppression of communication loss and miniaturization can be achieved.

A high frequency module (1; 1B) of a third aspect further includes a mounting board in the first aspect. A switch circuit (6; 6B) further includes a ground terminal (232c) connected to the first terminal (6a) to be switchable between connection and disconnection. A matching circuit (8) overlaps a first antenna terminal (5a) or the switch circuit (6; 6B) in a plan view from the thickness direction (D1) of a mounting board (20). The ground terminal (232c) is adjacent to the first terminal (6a).

According to this configuration, a signal path to the first antenna terminal (5a), the first terminal (6a), the ground terminal (232c), and the ground can be shortened. As a result, parasitic components (parasitic inductor and parasitic capacitance) generated in the signal path can be suppressed. As a result, it is possible to further suppress the pass loss (for example, deterioration in reception sensitivity and decrease in transmission power) in the signal path, which is in use.

A high frequency module (1) of a fourth aspect further includes a mounting board (20) in the first aspect. A matching circuit (8) is adjacent to a switch circuit (6) in a plan view from the thickness direction (D1) of the mounting board (20).

According to this configuration, the signal path between the matching circuit (8) and the switch circuit (6) can be shortened. As a result, parasitic components (parasitic inductor and parasitic capacitance) generated in the communication path can be suppressed. As a result, it is possible to further suppress the pass loss (for example, deterioration in reception sensitivity and decrease in transmission power) in the signal path, which is in use.

In a high frequency module (1) of a fifth aspect, a first terminal (6a) and a second terminal (6b) are disposed on a matching circuit (8) side inside a switch circuit (6) in a plan view from the thickness direction (D1) of a mounting board (20) in the fourth aspect.

According to the configuration, a signal path between the first terminal (6a) and the matching circuit (8) and a signal path between the second terminal (6b) and the matching circuit (8) can be shortened. As a result, parasitic components (parasitic inductor and parasitic capacitance) generated in the communication path can be suppressed. As a result, it is possible to suppress the pass loss (for example, deterioration in reception sensitivity and decrease in transmission power) in the signal path, which is in use.

In a high frequency module (1) of a sixth aspect, a matching circuit (8) includes an inductor (L1) in any one of the first to fifth aspects. The inductor (L1) is connected between a first signal path (K1) and a second signal path (K2).

According to this configuration, a high pass filter can be configured as the matching circuit (8).

In a high frequency module (1) of a seventh aspect, a matching circuit (8) includes a capacitor (C1) in any one of the first to fifth aspects. The capacitor (C1) is connected between a first signal path (K1) and a second signal path (K2).

According to this configuration, a low pass filter can be configured as the matching circuit (8).

In a high frequency module (1) of an eighth aspect, a matching circuit (8) includes an inductor (L2) and a capacitor (C2) in any one of the first to fifth aspects. The inductor (L2) and the capacitor (C2) are connected between a first signal path (K1) and a second signal path (K2), and are connected in parallel to each other.

According to this configuration, a band pass filter can be configured.

In a high frequency module (1) of a ninth aspect, a matching circuit (8) includes an inductor (L3) and a capacitor (C3) in any one of the first to fifth aspects. The inductor (L3) and the capacitor (C3) are connected between a first signal path (K1) and a second signal path (K2), and are connected in series to each other.

According to this configuration, a band elimination filter can be configured as the matching circuit (8).

In a high frequency module (1) of a tenth aspect, a matching circuit (8) further includes a capacitor (C4) in any one of the sixth to ninth aspects. The capacitor (C4) is connected between a first signal path (K1) and a ground.

According to the configuration, the matching circuit (8) can include the capacitor (C4) that functions only when the first signal path (K1) is used among the first signal path (K1) and the second signal path (K2). As a result, a circuit configuration of the matching circuit (8) can be changed with the signal path (the first signal path (K1) or the second signal path (K2)), which is in use.

In a high frequency module (1) of an eleventh aspect, a matching circuit (8) further includes an inductor (L4) in any one of the sixth to tenth aspects. The inductor (L4) is connected in series to a first signal path (K1).

According to the configuration, the matching circuit (8) can include the inductor (L4) that functions only when the first signal path (K1) is used among the first signal path (K1) and the second signal path (K2). As a result, a circuit configuration of the matching circuit (8) can be changed with the signal path (the first signal path (K1) or the second signal path (K2)), which is in use.

In a high frequency module (1) of a twelfth aspect, a matching circuit (8) includes an inductor formed in a pattern on a mounting board in any one of the third to fifth aspects.

According to this configuration, the miniaturization of the inductor can be achieved, and thus the miniaturization of the high frequency module (1; 1B) can be achieved.

In a high frequency module (1B) of a thirteenth aspect, a third terminal (6c) and a fourth terminal (6d) are each configured to be selectively connectable to a first terminal (6a), a second terminal (6b), and a ground in any one of the first to twelfth aspects. When one terminal among the third terminal (6c) and the fourth terminal (6d) is connected to the first terminal (6a) or the second terminal (6b), the other terminal among the third terminal (6c) and the fourth terminal (6d) is connected to the ground.

According to this configuration, when one terminal among the third terminal (6c) and the fourth terminal (6d) is connected to the first terminal (6a) or the second terminal (6b), the other terminal (not-in-use terminal) among the third terminal (6c) and the fourth terminal (6d) is connected to the ground. Therefore, it is possible to prevent the not-in-use terminal from being in a floating state. As a result, it is possible to suppress unnecessary signals from circulating from the not-in-use terminal to the signal path, which is in use.

In a high frequency module (1B) of a fourteenth aspect, a switch circuit (6B) further includes a first ground terminal (6e), a second ground terminal (6f), and a board (61) in any one of the first to thirteenth aspects. The first ground terminal (6e) is connected to the first terminal (6a) and the second terminal (6b) to be switchable between connection and disconnection. The first ground terminal (6e) is connected to the third terminal (6c) and the fourth terminal (6d) to be switchable between connection and disconnection. The first terminal (6a), the second terminal (6b), the first ground terminal (6e), and the second ground terminal (6f) are disposed on the board (61). In a plan view from the thickness direction of the board (61), a distance between the first terminal (6a) and the first ground terminal (6e) is defined as a first distance (T1), and a distance between the first terminal (6a) and the second ground terminal (6f) is defined as a second distance (T2). The first distance (T1) is shorter than the second distance (T2).

According to this configuration, a signal path between the first terminal (6a) and the first ground terminal (6e) can be shortened. As a result, parasitic components (parasitic inductor and parasitic capacitance) generated in the communication path can be further suppressed. As a result, it is possible to further suppress the pass loss (deterioration in reception sensitivity and decrease in transmission power) in the signal path, which is in use.

In a high frequency module (1B) of a fifteenth aspect, a switch circuit (6B) further includes a first ground terminal (6e), a second ground terminal (6f), and a board (61) in any one of the first to thirteenth aspects. The first ground terminal (6e) is connected to the first terminal (6a) and the second terminal (6b) to be switchable between connection and disconnection. The first ground terminal (6e) is connected to the third terminal (6c) and the fourth terminal (6d) to be switchable between connection and disconnection. The first terminal (6a), the second terminal (6b), the first ground terminal (6e), and the second ground terminal (6f) are disposed on the board (61). In a plan view from the thickness direction of the board (61), a distance between the first terminal (6a) and the first ground terminal (6e) is defined as a first distance (T1), a distance between the first terminal (6a) and the second ground terminal (6f) is defined as a second distance (T2), a distance between the second terminal (6b) and the first ground terminal (6e) is defined as a third distance (T3), and a distance between the second terminal (6b) and the second ground terminal (6f) is defined as a fourth distance (T4). The sum of the first distance (T1) and the third distance (T3) is shorter than the sum of the second distance (T2) and the fourth distance (T4).

According to this configuration, the sum of the first distance (T1) and the third distance (T3) is shorter than the sum of the second distance (T2) and the fourth distance (T4). Therefore, the sum of a signal path between the first terminal (6a) and the first ground terminal (6e), and a signal path between the second terminal (6b) and the first ground terminal (6e) can be shortened. As a result, parasitic components (parasitic inductor and parasitic capacitance) generated in the communication path can be suppressed. As a result, it is possible to suppress the pass loss (deterioration in reception sensitivity and decrease in transmission power) in the signal path, which is in use.

In a high frequency module (1B) of a sixteenth aspect, a switch circuit (6B) further includes a first ground terminal (6e), a second ground terminal (6f), and a board (61) in any one of the first to thirteenth aspects. The first ground terminal (6e) is connected to the first terminal (6a) and the second terminal (6b) to be switchable between connection and disconnection. The first ground terminal (6e) is connected to the third terminal (6c) and the fourth terminal (6d) to be switchable between connection and disconnection. The first terminal (6a), the second terminal (6b), the first ground terminal (6e), and the second ground terminal (6f) are disposed on the board (61). In a plan view from the thickness direction of the board (61), a distance between the first terminal (6a) and the first ground terminal (6e) is defined as a first distance (T1), and a distance between the first terminal (6a) and the second ground terminal (6f) is defined as a second distance (T2). The first distance (T1) and the third distance (T3) are each shorter than the second distance (T2) and the fourth distance (T4).

According to this configuration, a signal path between the first terminal (6a) and the first ground terminal (6e), and a signal path between the second terminal (6b) and the first ground terminal (6e) can be shortened. As a result, parasitic components (parasitic inductor and parasitic capacitance) generated in the communication path can be further suppressed. As a result, it is possible to further suppress the pass loss (deterioration in reception sensitivity and decrease in transmission power) in the signal path, which is in use.

A communication device (100) according to a seventeenth aspect includes the high frequency module (1; 1B) according to any one of the first to sixteenth aspects and a signal processing circuit (2). The signal processing circuit (2) is connected to the high frequency module (1; 1B) and performs signal processing on a high frequency signal.

According to this configuration, the communication device (100) having the effect of the high frequency module (1; 1B) can be obtained.

What is claimed is:

1. A high frequency module comprising:
a switch circuit that comprises a first terminal, a second terminal, a third terminal, and a fourth terminal;
a first antenna terminal that is connected to the first terminal by a first signal path;
a second antenna terminal that is connected to the second terminal by a second signal path;
a matching circuit that is connected between the first signal path and the second signal path;
a first filter that is connected to the third terminal and that is configured to connect to one of the first signal path and the second signal path; and
a second filter that is connected to the fourth terminal and that is configured to connect to the other of the first signal path and the second signal path,
wherein the first terminal and the second terminal are each configured to selectively connect to the third terminal, the fourth terminal, or ground, and
wherein when one of the first terminal and the second terminal is connected to the third terminal or the fourth terminal, the other of the first terminal and the second terminal is connected to ground.

2. A high frequency module comprising:
a switch circuit that comprises a first terminal, a second terminal, a third terminal, and a fourth terminal;
a first amplifier circuit that is connected to the first terminal by a first signal path;
a second amplifier circuit that is connected to the second terminal by a second signal path;
a matching circuit that is connected between the first signal path and the second signal path;
a first filter that is connected to the third terminal and that is configured to connect to one of the first signal path and the second signal path; and
a second filter that is connected to the fourth terminal and that is configured to connect to the other of the first signal path and the second signal path,
wherein the first terminal and the second terminal are each configured to selectively connect to the third terminal, the fourth terminal, and ground, and
wherein when one of the first terminal and the second terminal is connected to the third terminal or the fourth terminal, the other of the first terminal and the second terminal is connected to ground.

3. The high frequency module according to claim 1, further comprising:
a mounting board,
wherein the switch circuit further comprises a ground terminal that is selectively connected to the first terminal,
wherein the matching circuit overlaps the first antenna terminal or the switch circuit in a plan view from a thickness direction of the mounting board, and
wherein the ground terminal is adjacent to the first terminal.

4. The high frequency module according to claim 1, further comprising:
a mounting board,
wherein the matching circuit is adjacent to the switch circuit in a plan view from a thickness direction of the mounting board.

5. The high frequency module according to claim 4, wherein the first terminal and the second terminal are on a side of the switch circuit closest to the matching circuit in the plan view.

6. The high frequency module according to claim 1, wherein the matching circuit comprises an inductor connected between the first signal path and the second signal path.

7. The high frequency module according to claim 1, wherein the matching circuit comprises a capacitor connected between the first signal path and the second signal path.

8. The high frequency module according to claim 1, wherein the matching circuit is connected between the first signal path and the second signal path, and comprises an inductor and a capacitor that are connected in parallel to each other.

9. The high frequency module according to claim 1, wherein the matching circuit is connected between the first signal path and the second signal path, and comprises an inductor and a capacitor that are connected in series to each other.

10. The high frequency module according to claim 6, wherein the matching circuit further comprises a capacitor connected between the first signal path and the ground.

11. The high frequency module according to claim 6, wherein the matching circuit further comprises an inductor connected in series to the first signal path.

12. The high frequency module according to claim 3, wherein the matching circuit comprises an inductor formed in a pattern on the mounting board.

13. The high frequency module according to claim 1,
wherein the third terminal and the fourth terminal are each configured to selectively connect to the first terminal, the second terminal, or ground, and
wherein when one of the third terminal and the fourth terminal is connected to the first terminal or the second terminal, the other of the third terminal and the fourth terminal is connected to ground.

14. The high frequency module according to claim 1,
wherein the switch circuit further comprises:
a first ground terminal selectively connected to the first terminal and the second terminal,
a second ground terminal selectively connected to the third terminal and the fourth terminal, and
a board on which the first terminal, the second terminal, the first ground terminal, and the second ground terminal are disposed, and
wherein in a plan view from a thickness direction of the board:
a distance between the first terminal and the first ground terminal is a first distance,
a distance between the first terminal and the second ground terminal is a second distance, and
the first distance is shorter than the second distance.

15. The high frequency module according to claim 1,
wherein the switch circuit further comprises:
a first ground terminal selectively connected to the first terminal and the second terminal,
a second ground terminal selectively connected to the third terminal and the fourth terminal, and
a board on which the first terminal, the second terminal, the first ground terminal, and the second ground terminal are disposed, and
wherein in a plan view from a thickness direction of the board:
a distance between the first terminal and the first ground terminal is a first distance,
a distance between the first terminal and the second ground terminal is a second distance,
a distance between the second terminal and the first ground terminal is a third distance,
a distance between the second terminal and the second ground terminal is a fourth distance, and
a sum of the first distance and the third distance is shorter than a sum of the second distance and the fourth distance.

16. The high frequency module according to claim 1,
wherein the switch circuit further comprises:
a first ground terminal selectively connected to the first terminal and the second terminal,
a second ground terminal selectively connected to the third terminal and the fourth terminal, and
a board on which the first terminal, the second terminal, the first ground terminal, and the second ground terminal are disposed, and
wherein in a plan view from a thickness direction of the board:
a straight line distance between the first terminal and the first ground terminal is a first distance,
a straight line distance between the first terminal and the second ground terminal is a second distance,
a straight line distance between the second terminal and the first ground terminal is a third distance,
a straight line distance between the second terminal and the second ground terminal is a fourth distance, and
the first distance and the third distance are each shorter than the second distance and the fourth distance.

17. A communication device comprising:
the high frequency module according to claim 1; and
a signal processing circuit that is connected to the high frequency module and that is configured to perform signal processing on a high frequency signal.

18. A communication device comprising:
the high frequency module according to claim 2; and
a signal processing circuit that is connected to the high frequency module and that is configured to perform signal processing on a high frequency signal.
